(19) United States
(12) Patent Application Publication
(10) Pub. No.: US 2024/0427153 A1
(43) Pub. Date: Dec. 26, 2024

(54) LIGHT RECYCLING AND CONVERSION SYSTEMS FOR DISPLAY DEVICES

(71) Applicant: Meta Platforms Technologies, LLC, Menlo Park, CA (US)

(72) Inventors: Joshua Cobb, Victor, NY (US); Derek Wallin, Monroe, WA (US); Ajit Ninan, San Jose, CA (US); Chun Chi Wan, San Jose, CA (US)

(21) Appl. No.: 18/736,419

(22) Filed: Jun. 6, 2024

Related U.S. Application Data
(60) Provisional application No. 63/523,352, filed on Jun. 26, 2023.
(60) Provisional application No. 63/613,594, filed on Dec. 21, 2023.

(51) Int. Cl. F21V 9/14; F21Y 115/10; G02B 27/01; H01L 33/50; H01L 33/60; H04N 9/31

(52) U.S. Cl. CPC G02B 27/0172; H01L 33/502; H01L 33/60; H04N 9/3167

(57) ABSTRACT

A polarizing illuminator includes a light source, a collimator for collimating a light beam emitted by the light source, a parallel plate having a first surface and a second surface disposed at an acute angle with respect to the light beam, the first surface including a transmissive portion and a reflective portion, and the second surface including a reflective polarizer configured to reflect one polarization of the light beam, transmit an orthogonal polarization of the light beam, and split the light beam into first and second orthogonally polarized sub-beams, and a retarding wave plate disposed between the reflective portion of the first surface and the reflective polarizer, wherein the retarding wave plate is configured to rotate at least one of the first sub-beam and the second sub-beam to a matched polarization, and the first and second sub-beams having the matched polarization propagate parallel to each other.

### CROSS-REFERENCE TO RELATED APPLICATIONS

This application claims the benefit of priority under 35 U.S.C. § 119(e) of U.S. Provisional Application No. 63/523,352, filed Jun. 26, 2023, and U.S. Provisional Application No. 63/613,594, filed Dec. 21, 2023, the contents of which are incorporated herein by reference in their entirety.

### BRIEF DESCRIPTION OF THE DRAWINGS

The accompanying drawings illustrate a number of exemplary embodiments and are a part of the specification. Together with the following description, these drawings demonstrate and explain various principles of the present disclosure.

FIG. 1 is a schematic side view of a single-source polarizing illuminator using a transmissive polarization recovery plate according to some embodiments of the present disclosure.

FIG. 2 is a schematic side view of a display device with an image projector including an arrayed embodiment of the polarizing illuminator of FIG. 1 to illuminate a display panel of the image projector according to some embodiments.

FIG. 3 is a side ray-traced view of an embodiment of the image projector of FIG. 2 according to some embodiments.

FIG. 4 is a magnified view of the arrayed light source of FIG. 3 according to some embodiments.

FIGS. 5A and 5B are solid partial renderings of the illuminator of FIG. 3 at different viewing angles according to some embodiments.

FIG. 6 is a solid rendering of an illuminator using a reflective polarization recovery plate according to certain embodiments.

FIGS. 7A-7C are side cross-sectional views of example transmissive polarization recovery plates for use in the polarizing illuminator of FIGS. 1-3 and FIGS. 5A-5B according to various embodiments.

FIGS. 8A-8C are side cross-sectional views of example reflective polarization recovery plates for use in the polarizing illuminator of FIG. 6 according to certain embodiments of the present disclosure.

FIG. 9 is a flow chart of a method for recycling light in accordance with embodiments of this disclosure.

FIG. 10 is a view of a wearable display having a form factor of a pair of eyeglasses according to various embodiments.

FIG. 11 is a three-dimensional view of an HMD according to various embodiments.

FIG. 12 is an illustration of an example light conversion system in accordance with some embodiments.

FIG. 13 is an illustration of an example light conversion system in accordance with some embodiments.

FIG. 14 depicts the excitation of a quantum dot in accordance with certain embodiments.

FIG. 15 shows collimation of the bottom emission from the quantum dot of FIG. 14 according to some embodiments.

FIG. 16 illustrates the incorporation of a partial mirror over the quantum dot of FIG. 14 according to some embodiments.

FIG. 17 shows collimation of the emission from the quantum dot of FIG. 14 in response to top side excitation according to further embodiments.

FIG. 18 illustrates the incorporation of a short pass dichroic filter proximate to the quantum dot of FIG. 14 and collimated emission from the quantum dot in response to bottom side excitation according to particular embodiments.

FIG. 19 illustrates the incorporation of a long pass dichroic filter proximate to the quantum dot of FIG. 14 according to certain embodiments.

FIG. 20 illustrates the placement of a reflective polarizer and an optical element proximate to the quantum dot of FIG. 14 in accordance with various embodiments.

FIG. 21 depicts an array of emitters and quantum dots in accordance with certain embodiments.

FIG. 22 is a plan view of a quantum dot array in accordance with some embodiments.

FIG. 23 is a plan view of a quantum dot array with zonal controlled collimated illumination according to certain embodiments.

FIG. 24 is a plan view of a quantum dot array with global controlled collimated illumination according to certain embodiments.

FIG. 25 is an illustration of exemplary augmented-reality glasses that may be used in connection with embodiments of this disclosure.

FIG. 26 is an illustration of an exemplary virtual-reality headset that may be used in connection with embodiments of this disclosure.

FIG. 27 is an illustration of exemplary haptic devices that may be used in connection with embodiments of this disclosure.

FIG. 28 is an illustration of an exemplary virtual-reality environment according to various embodiments of this disclosure.

FIG. 29 is an illustration of an exemplary augmented-reality environment according to embodiments of this disclosure.

FIG. 30 is an illustration of an exemplary system that incorporates an eye-tracking subsystem capable of tracking a user's eye(s) according to certain embodiments of the disclosure.

FIG. 31 is a more detailed illustration of various aspects of the eye-tracking subsystem illustrated in FIG. 30 according to some embodiments of the disclosure.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the present disclosure covers all modifications, equivalents, and alternatives falling within the scope of the appended claims.

### DETAILED DESCRIPTION OF EXEMPLARY EMBODIMENTS

The present disclosure relates to optical modules for providing illumination, and visual display systems using such illuminators. The present disclosure also relates to light conversion systems for display devices.

Visual displays provide information to viewer(s) including still images, video, data, etc. Visual displays have applications in diverse fields including entertainment, education, engineering, science, professional training, advertising, to name just a few examples. Some visual displays, such as TV sets, display images to several users, while some visual display systems, such as near-eye displays (NEDs), are intended for individual users.

An artificial reality system generally includes an NED, e.g., a headset or a pair of glasses, configured to present content to a user. The NED may display virtual objects or combine images of real objects with virtual objects, as in virtual reality (VR), augmented reality (AR), or mixed reality (MR) applications. For example, in an AR/VR system, a miniature liquid crystal display may be used to provide images of virtual objects for observation by an eye of a user.

Because a display of HMD or NED is usually worn on a user's head, a large, bulky, unbalanced, and/or heavy display device with a heavy battery would be cumbersome and uncomfortable for the user to wear. Consequently, light engines or image projectors used in NED systems are advantageously small end energy-efficient. Display systems based on an array of light valves, such as liquid crystal display panels, require compact and efficient light sources configured to illuminate the liquid crystal panels with a minimum loss of light due to polarization, vignetting, color mismatch, geometrical constraints, etc.

Achieving optimal power and good image quality from small-scale display devices, such as liquid crystal on silicon (LCOS) displays, has been a challenge. Such displays commonly require polarized light and efficient light sources to maximize display illumination while reducing power consumption. Conventional display light sources are typically unpolarized and traditional polarization filters can greatly reduce the efficiency of light emitted since such filters eliminate non-selected polarizations. Liquid crystal display (LCD) screens commonly recycle light by reflecting it back to a reflector. However, LCOS and other such display panels may not include a surface to reflect back unpolarized light for recycling. Accordingly, a solution to reflect converted light without having to direct such light back to an LED (light-emitting diode) light source reflector surface is desirable.

The present disclosure is generally directed to light conversion systems for display devices, such as LCOS displays. In some embodiments, ultraviolet (UV) light may be used in conjunction with light conversion layers, such as quantum dot or phosphor layers, that can convert UV LED light to other wavelengths of light with high efficiency. UV LEDs are capable of producing UV light in a manner that is more efficient than other types of LEDs, such as visible spectrum light LEDs.

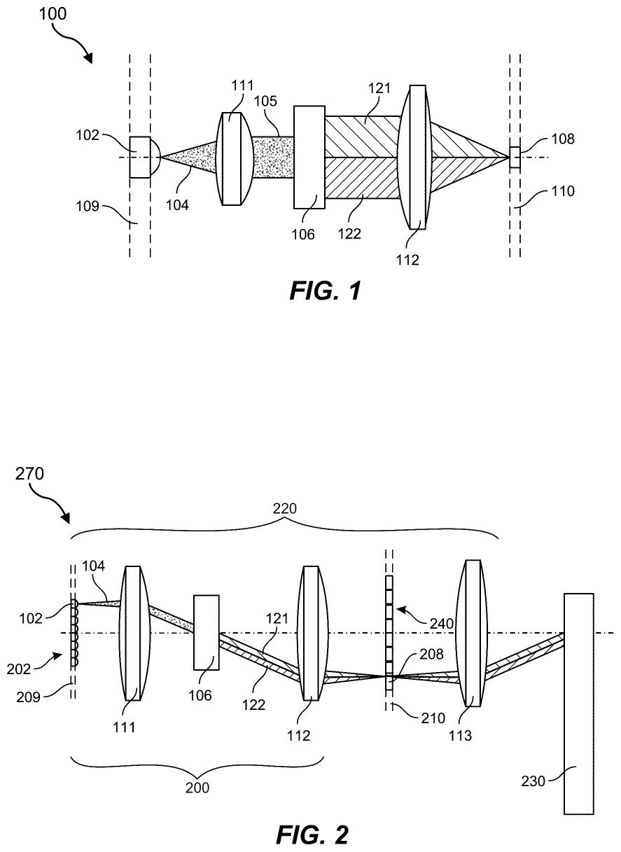

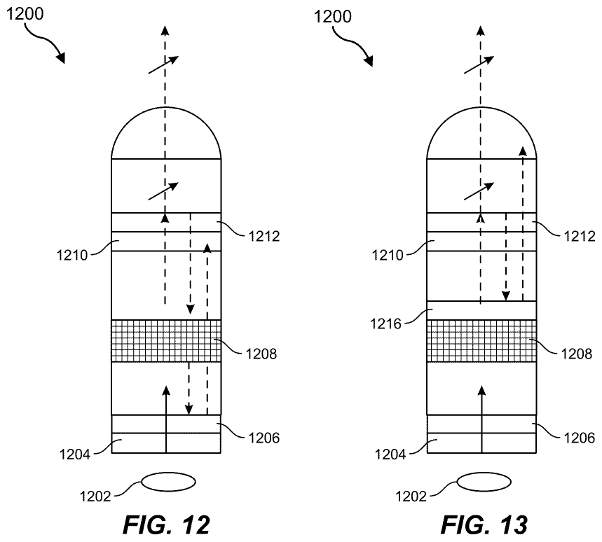

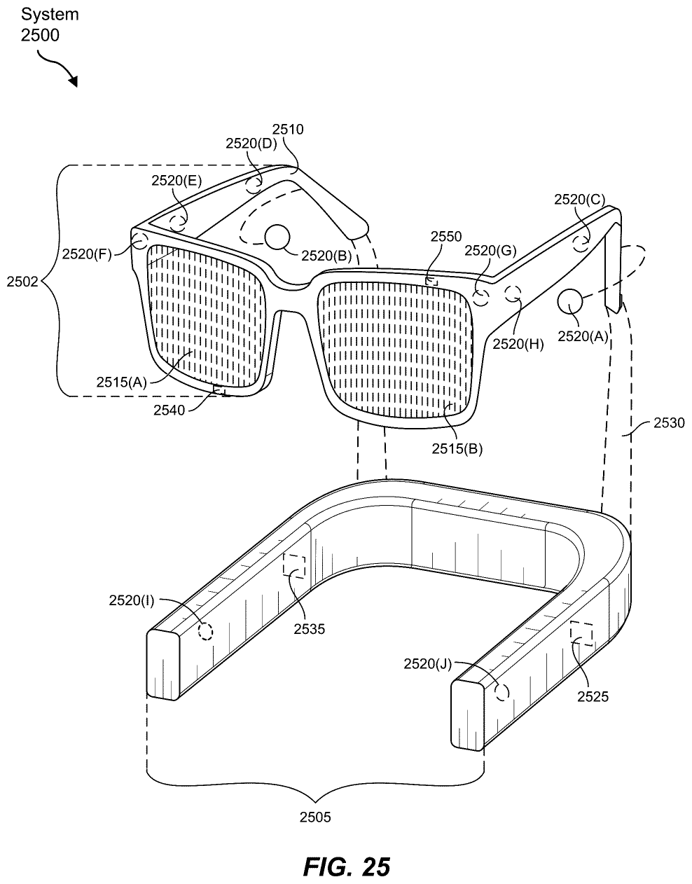

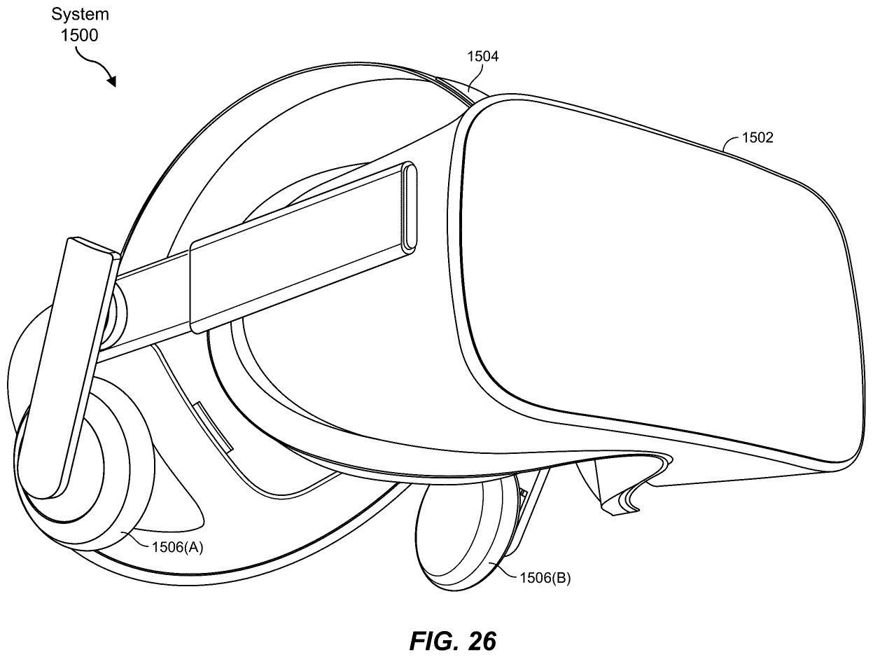

The following will provide, with reference to FIGS. 1-31, detailed descriptions of devices and related methods associated with light recycling and light conversion in display devices. The discussion associated with FIGS. 1-11 includes a description of a polarizing illuminator and projector with light recycling in a collimated beam path. The discussion associated with FIGS. 12-24 includes a description of a light conversion system for display devices. The discussion associated with FIGS. 25-31 relates to exemplary virtual reality and augmented reality devices that may include one or more light recycling or light conversion platforms as disclosed herein.

While the present teachings are described in conjunction with various embodiments and examples, it is not intended that the present teachings be limited to such embodiments. On the contrary, the present teachings encompass various alternatives and equivalents, as will be appreciated. All statements herein reciting principles, aspects, and embodiments of this disclosure, as well as specific examples thereof, are intended to encompass both structural and functional equivalents. Additionally, it is intended that such equivalents include both currently known equivalents as well as equivalents developed in the future, i.e., any elements developed that perform the same function, regardless of structure.

As used herein, the terms “first,” “second,” and so forth are not intended to imply sequential ordering, but rather are intended to distinguish one element from another, unless explicitly stated. Similarly, sequential ordering of method steps does not imply a sequential order of their execution, unless explicitly stated.

Unpolarized light sources, such as light-emitting diodes (LEDs), emit incoherent light suitable for the illumination of display panels, because incoherent light does not cause interference fringing of the illuminating light. One non-limiting example of a display panel is a liquid crystal (LC) panel. LEDs may be used in combination with polarizers converting unpolarized light emitted by the LEDs into polarized light for illuminating LC panels. However, half of the light energy is lost when polarizing LED light with a regular transmissive polarizer, which absorbs light at the unwanted orthogonal polarization.

Polarization recycling configurations may use reflective polarizers that reflect light at the unwanted polarization back to a diffusing reflector or a light scatterer, which converts a portion of the reflected light back to the required polarization state by a series of random reflections from the reflector or random scattering by the scatterer. Any non-converted portion is reflected back, and the process repeats until the reflected light energy is either absorbed by the reflector/scatterer or converted into the required polarization state. One drawback of polarization recycling is that a direction of propagation of the recycled light is typically not well defined. The direction of propagation of the recycled light is random or pseudo-random, causing the recycled light to behave much like scattered light. The scattered nature of the converted light impedes efficient utilization of the converted light for energy-efficient illumination of a display panel/spatial light modulator (SLM). Another drawback of polarization recycling is that the recycled light sometimes takes many passes through the recycling system due to the polarization not being controlled well. The more cycles undergone, the more the illuminating light is absorbed, and the less efficient the system becomes as a result.

In accordance with this disclosure, the energy of a light beam in a polarization state reflected by a reflective polarizer may be utilized more efficiently if the light path of the reflected light is pre-determined, pre-optimized, and/or pre-configured, such that the recycled light propagates through the reflective polarizer in a well-defined, well-directed state, as a collimated or a nearly-collimated light beam. Such a configuration allows one to design the propagation path of the recycled light to selectively illuminate particular pixels or pixel groups of an SLM. For example, a same SLM pixel group or zone may be illuminated with recycled and non-recycled light beam portions at different angles of incidence.

The recovered or recycled light may take a single pass through the recycling optical train. The polarization is well controlled, so that it is not just a random polarization where a portion is recycled and another portion passes through the recycling again. In a polarizing illuminator of this disclosure, the recycled light may be altered to the desired polarization at the first pass. The efficient, pre-determined, single-pass utilization of recycled collimated light beams improves the overall light utilization efficiency and wall plug efficiency of a visual display relying on a display panel/SLM to generate visual images. The path of the recovered light may be formed in a collimated beam space, enabling one to use a single optical element for polarization recovery of an arrayed light source, making the configuration amenable to zonal illumination with polarization recovery.

Referring now to FIG. 1, a polarizing illuminator 100 includes a light source 102, e.g., a semiconductor light source such as a light-emitting diode (LED) or a superluminescent light-emitting diode (SLED), for providing an unpolarized light beam 104. The light source 102 may include a microlens for conditioning the light beam 104 parameters such as the spatial distribution and angular distribution of the light beam 104. A first collimator 111 collimates the light beam 104 to provide a substantially parallel beam 105. A polarizer 106 splits the parallel light beam 105 into first 121 and second 122 orthogonally polarized sub-beams. The polarizer 106 further rotates a polarization of the second sub-beam 122 to match a polarization of the first sub-beam 121. The first 121 and second 122 identically polarized sub-beams propagate parallel to one another. Since the polarizer 106 polarizes most of the parallel beam 105, it is termed a “full” polarizer herein. The term “full” does not necessarily imply a 100% polarization efficiency, however, as it only implies that both polarizations of light are used at the output, none being rejected. Non-limiting example configurations of the polarizer 106 will be provided further below.

A second collimator 112 receives and focuses the first 121 and second 122 sub-beams to a common spot or location 108 to be illuminated. As illustrated by FIG. 1, the first 121 and second 122 sub-beams provide two complementary portions of the illuminating light cone to the location 108. It is to be noted that the polarizing illuminator 100 lends itself to an arrayed configuration, with an array of the light sources 102 (not shown in FIG. 1) disposed in a source plane 109, and an array of pixels of a display panel (not shown in FIG. 1) placed in an illumination plane 110. In some embodiments, the configuration of the polarizing illuminator 100 is telecentric, with the source plane 109 and the polarizer 106 being disposed one focal length of the first collimator 111 away from the first collimator 111, and the illumination plane 110 and the full polarizer 106 being disposed one focal length of the second collimator 112 away from the second collimator 112.

The arrayed configuration is illustrated in FIG. 2, which shows a display device 270 including an image projector 220 coupled to a replicating lightguide 230. The image projector 220 includes an arrayed polarizing illuminator 200 illuminating a display panel 240, or more generally a spatial light modulator (SLM), which may be transmissive, reflective, scattering, etc. The transmissive display panel 240 is disposed in an illumination plane 210 of the arrayed polarizing illuminator 200. The arrayed polarizing illuminator 200 is similar in construction and function to the polarizing illuminator 100 of FIG. 1. The arrayed polarizing illuminator 200 of FIG. 2 includes an array 202 of the light sources 102 (FIG. 1) disposed in a source plane 209, the first 111 and second 112 collimators, and the polarizer 106. The telecentric configuration enables light emitted by each light source 102 to illuminate a particular area of pixels 208 of the transmissive display panel 240 with polarized light converted to a single polarization state with nearly 100% efficiency. A zonal illumination of the transmissive display panel 240 is possible, with each area of pixels 208 or a group or zone of pixels 208 being illuminated with a particular light source 102 of the array 202. The zonal illumination allows one to enhance the overall contrast of the displayed image, as well as to preserve energy. The image projector 220 further includes a third collimator 113 for projecting an image displayed by the transmissive display panel 240 onto the replicating lightguide 230.

In operation, the arrayed polarizing illuminator 200 illuminates the transmissive display panel 240, which forms an image in linear domain. Herein, the term “image in linear domain” means an image where individual pixels (elements of the image) are represented by corresponding ray coordinates, and accordingly the term “image in angular domain” means an image where individual pixels are represented by corresponding ray angles. The third collimator 113 operates as an “offset-to-angle” element converting ray coordinate, i.e., a pixel coordinate of the display panel 240, into ray angle at the replicating lightguide 230. The image in angular domain may be observed by a viewer's eye directly; the optional replicating lightguide 230 operates to expand the exit pupil of the image projector 220 by in-coupling the image light carrying an image in angular domain and out-coupling laterally offset portions of the image light while preserving its angular distribution, or in other words preserving the image to be displayed.

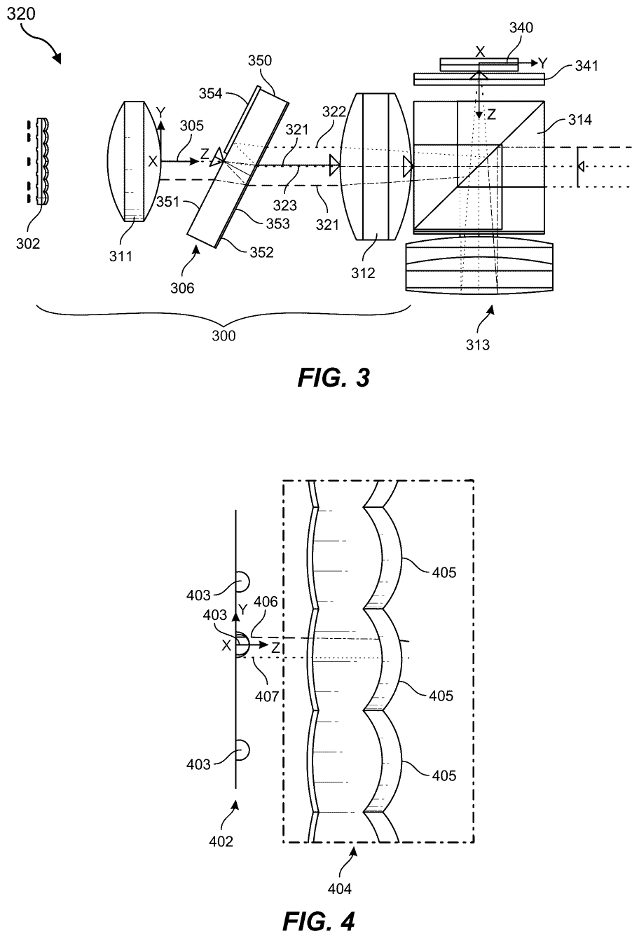

Turning to FIG. 3, a polarization-folded image projector 320 is a non-limiting example embodiment of the image projector 220 of FIG. 2, and operates in a similar manner. The polarization-folded image projector 320 includes an arrayed polarizing illuminator 300 illuminating a reflective display panel 340, e.g., a liquid crystal on silicon (LCoS) panel. The arrayed polarizing illuminator 300 is similar to the arrayed polarizing illuminator 200 of FIG. 2. The arrayed polarizing illuminator 300 of FIG. 3 includes an array 302 of light sources, first 311 second 312 collimators, and a polarization recovery plate 306, which is an embodiment of the polarizer 106 of the polarizing illuminator 100 of FIG. 1.

The polarization recovery plate 306 of the polarizing illuminator 300 of FIG. 3 includes a plano-parallel transparent plate or substrate 350 having first 351 and second 352 opposed parallel surfaces, an offset full reflector 354 supported by a first surface 351, and a stack 353 of a quarter-wave retarder and reflective polarizer supported by a second surface 352. The polarization recovery plate 306 is tilted away from normal incidence. Herein, the term “full reflector” does not imply 100% reflectivity. It means that most of the impinging energy is reflected, the reflectivity being in the range of e.g., 70% to 100%.

In operation, unpolarized light emitted by one of the array 302 of light sources is collimated by the first collimator 311 forming a collimated light beam 305, which impinges onto the first surface 351 of the substrate 350 of the polarization recovery plate 306 below the offset full reflector 354. The collimated light beam 305 propagates through the substrate 350 and impinges onto the stack 353, which transmits a first sub-beam 321 in a desired first polarization state and reflects a second sub-beam 322 to propagate back through the substrate 350. The second sub-beam 322 impinges onto the offset full reflector 354, which reflects it back through the substrate 350 and towards the stack 353. Upon the double propagation through the quarter-wave retarder of the stack 353, the second sub-beam 322 adopts the first polarization state and is thus transmitted by the reflective polarizer of the stack 353. In this manner, two collimated parallel sub-beams 321 and 322 at a same polarization state are formed.

The first 321 and second 322 collimated sub-beams are focused by the second collimator 312 onto the reflective display panel 340 through a window 341. A polarization beamsplitter (PBS) 314 is used for polarization path folding, where the first 321 and second 322 collimated sub-beams are directed towards the reflective display panel 340 on a first pass through the PBS 314, and the reflected image light is directed to the third collimator 313 on the second pass through the PBS 314. The third collimator 313 includes reflective and refractive surfaces. The PBS 314 then redirects the collimated light beam carrying an image in angular domain (as explained above with respect to FIG. 2) towards the viewer, either directly or through a replicating lightguide, not shown.

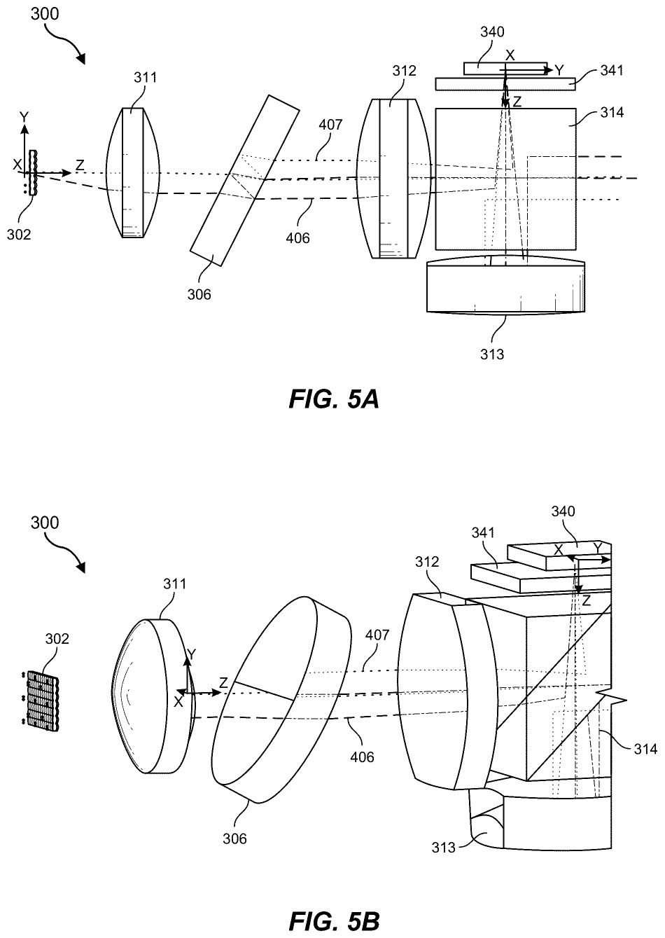

The path 323 of light in FIG. 3 can be understood by referring to FIG. 4, which shows a magnified view of the array 302 of light sources of FIG. 3, including an array 402 of micro-LEDs 403 operably coupled to an array 404 of lenslets 405. Each lenslet 405 of the lenslet array 404 collimates or pre-conditions light emitted by a corresponding LED 403 of the micro-LED array 402, providing the required spatial and angular distributions. Lines 407 and lines 406 denote opposite boundary rays of one of the micro-LEDs 403. The lines 407 and lines 406 are traced through the polarization-folded image projector 320 of FIG. 3. Since the boundary ray 407 in FIG. 4 propagates through the middle of the central lenslet 405, the micro-LEDs 403 are offset relative to optical axes of the lenslets. The offset may be selected to properly steer the rays relative to the offset full reflector 354. Alternatively, the micro-LEDs 403 may remain centered with respect to the lenslets 405, i.e., with no offset or zero offset, and the vertical position of the polarization recovery plate 306 and the offset full reflector 354 may be adjusted to propagate the first sub-beam 321 while reflecting the second sub-beam 322, as explained above. FIGS. 5A and 5B show the lines 407 and lines 406 traced through the polarizing illuminator 300.

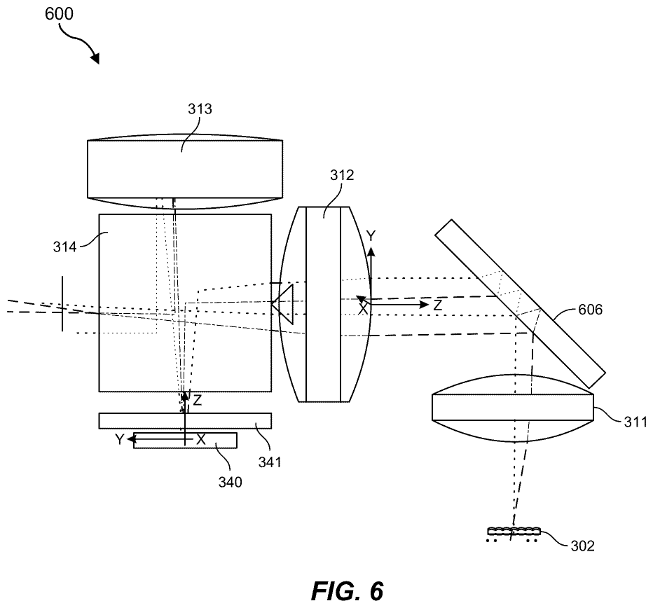

FIG. 6 shows an alternative reflective configuration for polarization recycling. An arrayed polarizing illuminator 600 uses a reflective polarization recovery plate 606. Transmissive and reflective polarization recovery plate example implementations will now be described in more detail.

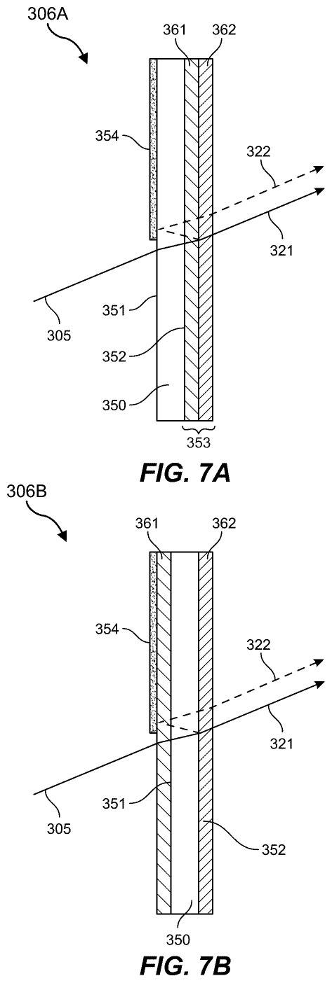

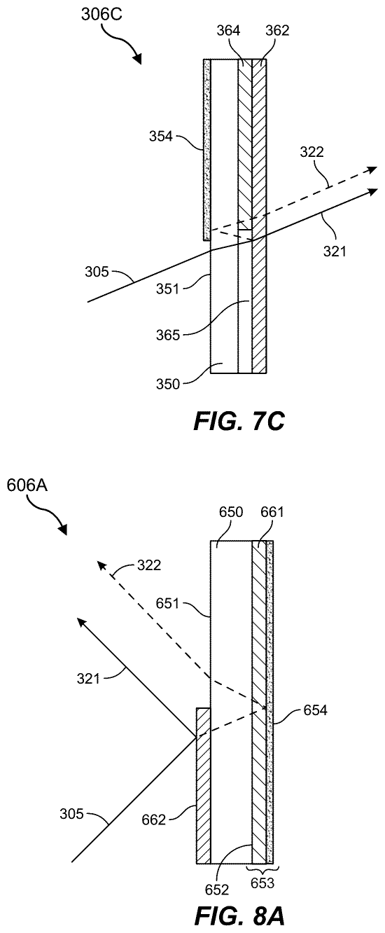

Referring first to FIG. 7A with further reference to FIG. 3, a polarization recovery plate 306A is an embodiment of the transmissive polarization recovery plate 306 of FIG. 3. The polarization recovery plate 306A of FIG. 7A includes the plano-parallel transparent substrate 350, e.g., a glass, fused silica, plastic etc. substrate, having first 351 and second 352 opposed parallel surfaces. The first surface 351 supports the offset full reflector 354. The second surface 352 supports a stack 353 of a quarter-wave retarder 361 and reflective polarizer 362.

In operation, the collimated light beam 305 impinges at an acute angle onto the first surface 351 under the offset full reflector 354. The collimated light beam 305 propagates through the substrate 350 and the quarter-wave retarder 361 and impinges onto the reflective polarizer 362, which transmits the first sub-beam 321 in the desired first polarization state, and reflects the second sub-beam 322 in an orthogonal polarization state to propagate back through the quarter-wave retarder 361 and the substrate 350. The second sub-beam 322 impinges onto the offset full reflector 354 from inside the substrate 350. The offset full reflector 354 reflects the second sub-beam 322 back through the substrate 350 and the quarter-wave retarder 361. The optical axis of the quarter-wave retarder 361 is oriented such that upon the double propagation through the quarter-wave retarder 361, the second sub-beam 322 adopts the first polarization state and is thus transmitted by the reflective polarizer 362 of the stack 353. In this manner, two collimated parallel sub-beams 321 and 322 at a same polarization state are formed.

Turning to FIG. 7B with further reference to FIG. 3, a polarization recovery plate 306B is another non-limiting example of the transmissive polarization recovery plate 306 of FIG. 3. In the transmissive recovery plate 306B of FIG. 7B, the quarter-wave retarder 361 is coupled not to the second 352 but to the first 351 surface of the plano-parallel transparent substrate 350, the offset full reflector 354 being supported by the quarter-wave retarder 361. The second surface 352 of the plano-parallel transparent substrate 350 supports the reflective polarizer 362.

The operation of the polarization recovery plate 306B is similar to that of the polarization recovery plate 306A of FIG. 7A. Briefly, the collimated light beam 305 propagates through the substrate 350 and impinges onto the reflective polarizer 362, which transmits the first sub-beam 321 in the desired first polarization state, and reflects the second sub-beam 322 in an orthogonal, second polarization state to propagate back through the substrate 350 and quarter-wave retarder 361. The second sub-beam 322 impinges onto the offset full reflector 354, which reflects the second sub-beam 322 back through the quarter-wave retarder 361 and the substrate 350. Upon the double propagation through the quarter-wave retarder 361, the second sub-beam 322 adopts the first polarization state and is thus transmitted by the reflective polarizer 362. The polarization recovery plate 306B forms two collimated parallel sub-beams 321 and 322 in a same polarization state.

Referring now to FIG. 7C with further reference to FIG. 3, a polarization recovery plate 306C is yet another non-limiting example of the transmissive polarization recovery plate 306 of FIG. 3. The transmissive polarization recovery plate 306C includes the plano-parallel transparent substrate 350 having the first 351 and second 352 opposed parallel surfaces. The first surface 351 supports the offset full reflector 354. The second surface 352 supports an offset half-wave retarder 364 and an optional transparent spacer 365 e.g., a glass or fused silica plate, which in turn support the reflective polarizer 362.

In operation, the collimated light beam 305 impinges at an acute angle onto the first surface 351 under the offset full reflector 354. The collimated light beam 305 propagates through the substrate 350 and the spacer 365 and impinges onto the reflective polarizer 362, which transmits the first sub-beam 321 in the desired first polarization state, and reflects the second sub-beam 322 in an orthogonal second polarization state to propagate back through the spacer 365 and the substrate 350. The second sub-beam 322 impinges onto the offset full reflector 354 from inside the substrate 350. The offset full reflector 354 reflects the second sub-beam 322 back through the substrate 350 and the offset half-wave retarder 364. The optical axis of the half-wave retarder 364 is aligned such that the second sub-beam 322 adopts the first polarization state and is thus transmitted through the reflective polarizer 362. Thus, the polarization recovery plate 306C forms two collimated parallel sub-beams 321 and 322 in a same polarization state.

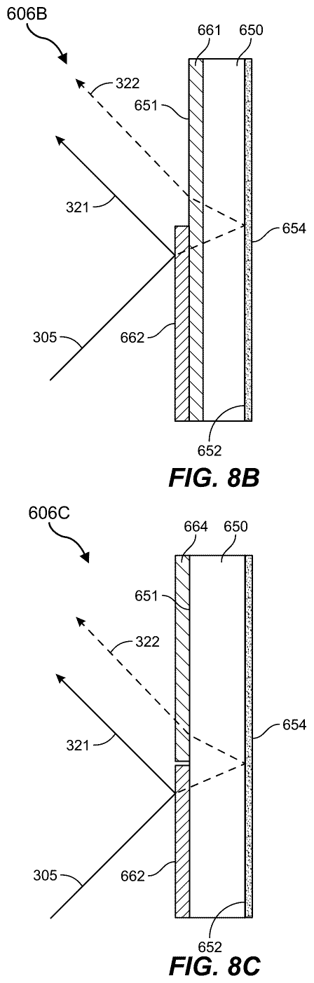

Referring to FIG. 8A with further reference to FIG. 6, a polarization recovery plate 606A is an embodiment of the reflective polarization recovery plate 606. The polarization recovery plate 606A of FIG. 8A includes a plano-parallel transparent substrate 650, e.g., a glass, fused silica, plastic, etc. substrate, having first 651 and second 652 opposed parallel surfaces. The first surface 651 supports an offset reflective polarizer 662 only covering a portion of the first surface 651. The second surface 652 supports a stack 653 of a quarter-wave retarder 661 and full reflector 654.

In operation, the collimated light beam 305 impinges at an acute angle onto the offset reflective polarizer 662, which reflects the first sub-beam 321 having the desired polarization state and transmits the second sub-beam 322 having the orthogonal polarization state, to propagate through the substrate 650 and the quarter-wave retarder 661. The second sub-beam 322 reflects from the full reflector 654 and propagates back through the quarter-wave retarder 661. Upon the double propagation through the properly oriented quarter-wave retarder 661, the second sub-beam 322 adopts the first polarization state, propagates back through the substrate 650, and exits the reflective polarization recovery plate 606A. In this manner, two collimated parallel sub-beams 321 and 322 in a same polarization state are formed.

Turning to FIG. 8B with further reference to FIG. 6, a polarization recovery plate 606B is another non-limiting example of the reflective polarization recovery plate 606 of FIG. 6. The polarization recovery plate 606B of FIG. 8B includes the plano-parallel transparent substrate 650 having the first 651 and second 652 opposed parallel surfaces. The first surface 651 supports the quarter-wave retarder 661, which supports the offset reflective polarizer 662 only covering a portion of the quarter-wave retarder 661. The second surface 652 supports the full reflector 654. As compared to the polarization recovery plate 606A of FIG. 8A, the quarter-wave retarder 661 is moved to the other side of the transparent substrate 650.

In operation, the collimated light beam 305 impinges at an acute angle onto the offset reflective polarizer 662, which reflects the first sub-beam 321 having the desired polarization state, and transmits the second sub-beam 322 having the orthogonal polarization state to propagate through the quarter-wave retarder 661 and the substrate 650. The second sub-beam 322 reflects from the full reflector 654, and propagates back through the substrate 650 and the quarter-wave retarder 661. Upon the double propagation through the properly oriented quarter-wave retarder 661, the second sub-beam 322 adopts the first polarization state, and exits the reflective polarization recovery plate 606B. Thus, two collimated parallel sub-beams 321 and 322 in a same polarization state are formed.

Turning now to FIG. 8C with further reference to FIG. 6, a polarization recovery plate 606C is another non-limiting example of the reflective polarization recovery plate 606 of FIG. 6. The polarization recovery plate 606C of FIG. 8C includes a plano-parallel transparent substrate 650 having the first 651 and second 652 opposed parallel surfaces. The first surface 651 supports the offset reflective polarizer 662 and an offset half-wave retarder 664 disposed on the first surface 651 adjacent the offset reflective polarizer 662 such that the offset reflective polarizer 662 only covers a portion of the first surface 351. The second surface 652 supports the full reflector 654.

In operation, the collimated light beam 305 impinges at an acute angle onto the offset reflective polarizer 662, which reflects the first sub-beam 321 having the desired polarization state, and transmits the second sub-beam 322 having the orthogonal polarization state to propagate through the substrate 650. The second sub-beam 322 reflects from the full reflector 654 and propagates back through the substrate 650 and the offset half-wave retarder 664. The axis of the half-wave retarder 664 is oriented to rotate the second polarization to be the same as the first polarization. In this manner, two collimated parallel sub-beams 321 and 322 in a same polarization state are formed.

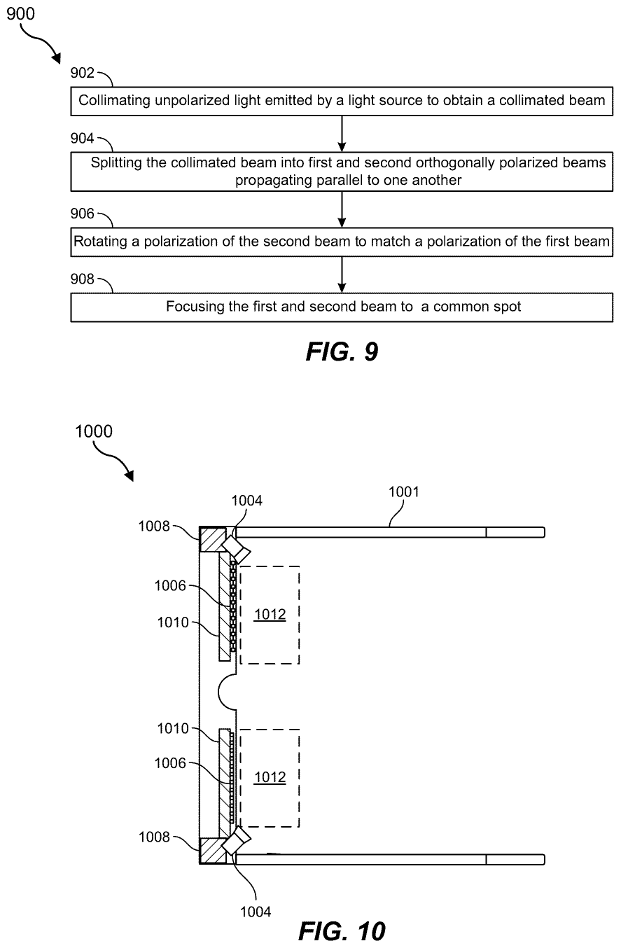

Referring to FIG. 9 with further reference to FIG. 1, a method 900 (FIG. 9) for recycling light includes collimating (902) unpolarized light emitted by a light source to obtain a collimated beam, for example collimating the unpolarized light 104 by the first collimator 111 (FIG. 1) to obtain a collimated beam, e.g., the collimated beam 105 in FIG. 1. The collimated beam is split (904) into first and second orthogonally polarized sub-beams, and a polarization of the second sub-beam is rotated (906) to match a polarization of the first sub-beam, such that the first and second sub-beams propagate parallel to one another. Alternatively, both polarizations may be rotated towards each other. Then, the first and second sub-beams are focused (908), e.g., using the second collimator 112 in FIG. 1.

Referring now to FIG. 10, an augmented reality (AR) near-eye display 1000 includes a frame 1001 having a form factor of a pair of eyeglasses. The frame 1001 supports, for each eye: a projector 1008 including any polarizing illuminator/image projector described herein, a pupil-replicating waveguide 1010 optically coupled to the projector 1008, an eye-tracking camera 1004, a plurality of illuminators 1006, and an eye-tracking camera controller (not shown). The illuminators 1006 may be supported by the pupil-replicating waveguide 1010 for illuminating an eyebox 1012. The projector 1008 provides a fan of light beams carrying an image in angular domain to be projected into a user's eye. The pupil-replicating waveguide 1010 receives the fan of light beams and provides multiple laterally offset parallel copies of each beam of the fan of light beams, thereby extending the projected image over the eyebox 1012.

For AR applications, the pupil-replicating waveguide 1010 can be transparent or translucent to enable the user to view the outside world together with the images projected into each eye and superimposed with the outside world view. The images projected into each eye may include objects disposed with a simulated parallax, so as to appear immersed into the real world view.

The purpose of the eye-tracking cameras 1004 is to determine position and/or orientation of both eyes of the user. Once the position and orientation of the user's eyes are known, a gaze convergence distance and direction may be determined. The imagery displayed by the projectors 1008 may be adjusted dynamically to account for the user's gaze, for a better fidelity of immersion of the user into the displayed augmented reality scenery, and/or to provide specific functions of interaction with the augmented reality.

In operation, the illuminators 1006 illuminate the eyes at the corresponding eyeboxes 1012, to enable the eye-tracking cameras to obtain the images of the eyes, as well as to provide reference reflections i.e., glints. The glints may function as reference points in the captured eye image, facilitating the eye gazing direction determination by determining position of the eye pupil images relative to the glints images. To avoid distracting the user with illuminating light, the latter may be made invisible to the user. For example, infrared light may be used to illuminate the eyeboxes 1012.

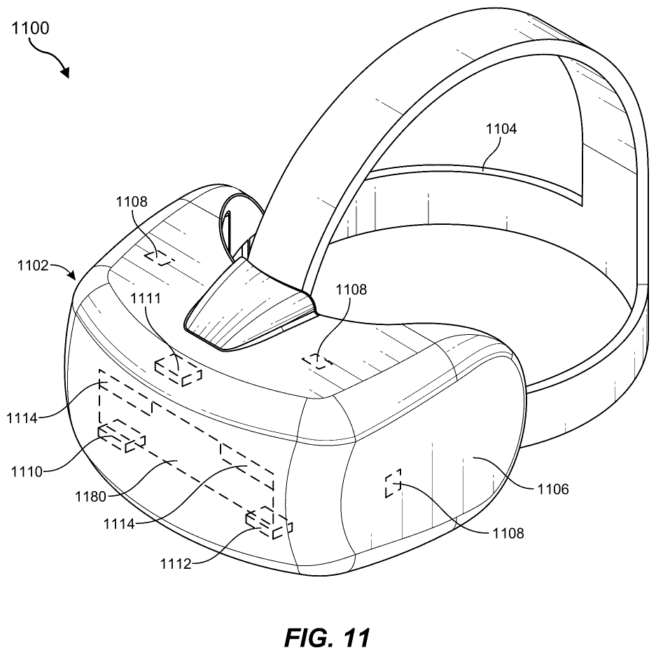

Turning to FIG. 11, an HMD 1100 is an example of an AR/VR wearable display system which encloses the user's face, for a greater degree of immersion into the AR/VR environment. The HMD 1100 may generate the entirely virtual 3D imagery. The HMD 1100 may include a front body 1102 and a band 1104 that can be secured around the user's head. The front body 1102 is configured for placement in front of the eyes of a user in a reliable and comfortable manner. A display system 1180 may be disposed in the front body 1102 for presenting AR/VR imagery to the user. The display system 1180 may include any of the image projectors disclosed herein. Sides 1106 of the front body 1102 may be opaque or transparent.

In some embodiments, the front body 1102 includes locators 1108 and an inertial measurement unit (IMU) 1110 for tracking acceleration of the HMD 1100, and position sensors 1112 for tracking position of the HMD 1100. The IMU 1110 is an electronic device that generates data indicating a position of the HMD 1100 based on measurement signals received from one or more of position sensors 1112, which generate one or more measurement signals in response to motion of the HMD 1100. Examples of position sensors 1112 include: one or more accelerometers, one or more gyroscopes, one or more magnetometers, another suitable type of sensor that detects motion, a type of sensor used for error correction of the IMU 1110, or some combination thereof. The position sensors 1112 may be located external to the IMU 1110, internal to the IMU 1110, or some combination thereof.

The locators 1108 are traced by an external imaging device of a virtual reality system, such that the virtual reality system can track the location and orientation of the entire HMD 1100. Information generated by the IMU 1110 and the position sensors 1112 may be compared with the position and orientation obtained by tracking the locators 1108, for improved tracking accuracy of position and orientation of the HMD 1100. Accurate position and orientation is important for presenting appropriate virtual scenery to the user as the latter moves and turns in 3D space.

The HMD 1100 may further include a depth camera assembly (DCA) 1111, which captures data describing depth information of a local area surrounding some or all of the HMD 1100. The depth information may be compared with the information from the IMU 1110, for better accuracy of determination of position and orientation of the HMD 1100 in 3D space.

The HMD 1100 may further include an eye tracking system 1114 for determining orientation and position of a user's eyes in real time. The obtained position and orientation of the eyes also allows the HMD 1100 to determine the gaze direction of the user and to adjust the image generated by the display system 1180 accordingly. The determined gaze direction and vergence angle may be used to adjust the display system 1180 to reduce the vergence-accommodation conflict. The direction and vergence may also be used for the display's exit pupil steering as disclosed herein. Furthermore, the determined vergence and gaze angles may be used for interaction with the user, highlighting objects, bringing objects to the foreground, creating additional objects or pointers, etc. An audio system may also be provided including e.g., a set of small speakers built into the front body 1102.

FIGS. 12 and 13 illustrate light conversion systems that may efficiently produce and recycle converted polarized light for displays in accordance with various embodiments. As shown in FIG. 12, a light conversion system 1200 may utilize UV light that may be generated by a high-energy light source 1202, which may, for example, be a UV LED that produces light having a wavelength of approximately 405 nm. Light from high-energy light source 1202 may first pass through a UV pass filter 1204 and then through a reflective filter 1206 (e.g., a red reflective filter in the example shown) that permits ready passage of the UV light. The UV proceeds to color-conversion layer 1208 (e.g., an array of quantum dots) that converts the UV light to a particular color of light (e.g., R/G/B). In the examples illustrated in FIGS. 12 and 13, color-conversion layer 1208 converts the UV light to red light.

The converted light from color-conversion layer 1208 is unpolarized and emits in all directions. Accordingly, system 1200 may contain the converted red light and send it upward after reflecting the light from reflective filter 1206 such that the converted red light is directed toward the emission path. The converted red light and other light passing through color-conversion layer 1208 then hits a UV filter 1210, which reflects or filters unconverted UV light. UV light reflected from UV filter 1210 may be directed back toward color-conversion layer 1208 to be converted. Converted light, such as the red light shown, passes through UV filter 1210 and hits a reflective polarizer 1212. Reflective polarizer 1212 may, for example, be a nano-wire grid polarizer (NWGP) that allows the converted red light with one axis of light to pass while reflecting all other non-aligned light.

The converted red light reflected from reflective polarizer 1212 passes back through color-conversion layer 1208, where some of the red light may be absorbed while most of the red light is reflected back by color-conversion layer 1208. The red converted light may be reflected between reflective polarizer 1212 and color-conversion layer 1208 one or more additional times, with depolarization occurring at each reflection with some component aligned to the axis of reflective polarizer 1212, until the red light has the correct polarization to pass through reflective polarizer 1212. Although the system has been described in the context of UV to red light conversion, similar systems may be utilized with different color conversion layers and corresponding reflectors to convert UV light to other colors, such as blue or green.

In further embodiments, the excitation light source may include an array of modulated excitation light sources and/or the color conversion materials may include an array of spatially separated color conversion material segments, i.e., arranged as a pattern. The number of excitation light sources and the number of color conversion material segments may be equal or unequal. In some aspects, the excitation light sources may be larger than the individual color conversion material segments. Moreover, the modulated excitation light sources may be individually modulated or grouped to provide localized excitation of the color conversion material segments. Additional array optics and flat optics with wavelength and/or polarization transmission/reflection selectivity can be integrated with the excitation light source array and color conversion material array to optimize the geometric efficiency for excitation, including modulated and localized excitation and for reemission by color conversion.

FIG. 13 illustrates a system 1300 that is similar to system 1200 in FIG. 12 but further includes an additional reflective filter 1316 (e.g., a red reflection layer) that reflects red light from reflective polarizer 1212 rather than allowing the light to pass back to color-conversion layer 1208.

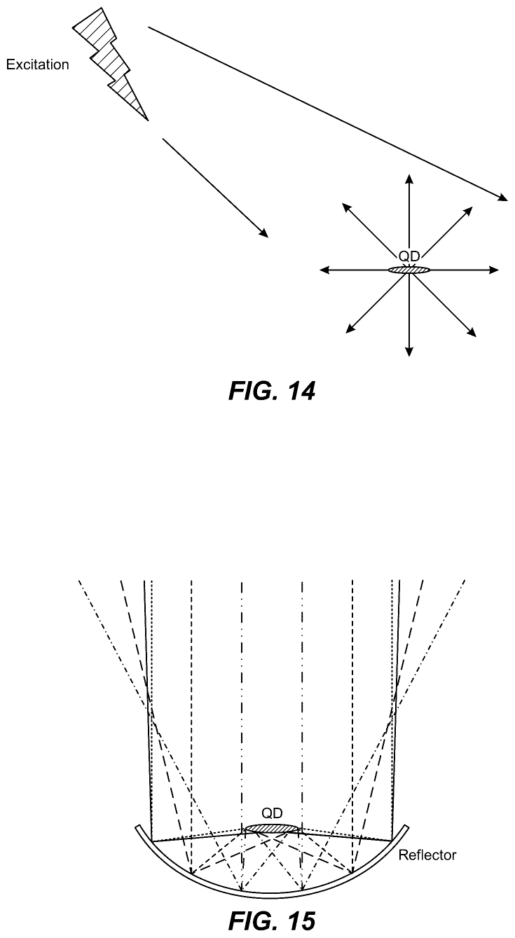

The architecture and operation of an example collimated illumination panel is illustrated schematically in FIGS. 14-24. In particular embodiments, the illumination panel may be configured to convert the light emitted by a quantum dot into a collimated bundle of light. A quantum dot may generate output radiation via photoluminescence. Referring to FIG. 14, depicted is the excitation and the resulting isotropic emission from a quantum dot. An excitation source may be configured to emit blue light or ultraviolet light, for example, and stimulate the emission of radiation from the quantum dot. An excitation source may include a blue light emitting diode (LED), for example.

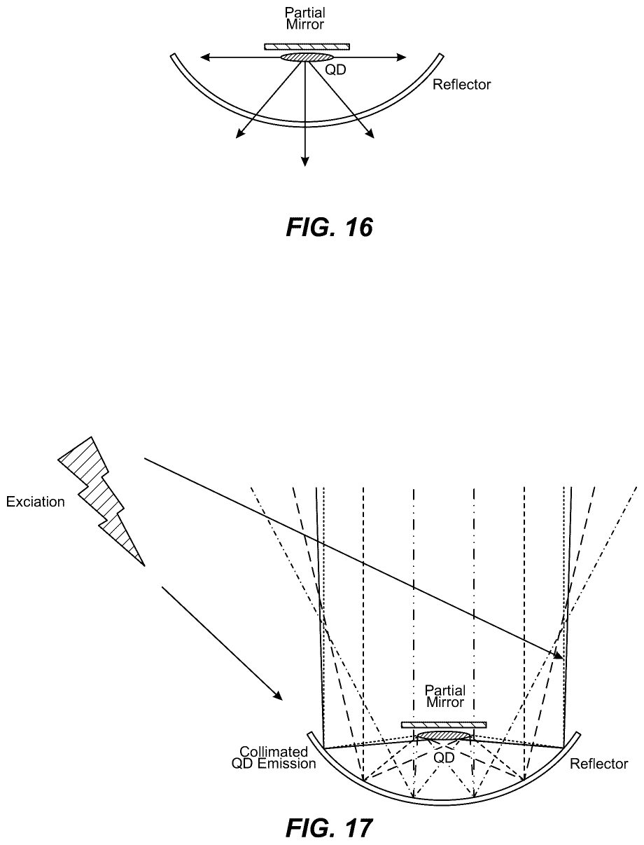

As shown in FIG. 15, the bottom side emission from the quantum dot may be redirected and collimated by locating a curved reflector proximate to the bottom side of the quantum dot. The location, size, and shape of the reflector may be chosen to impact the directionality and degree of collimation of the reflected light. In addition to the reflector, top side emission from the quantum dot may be effectively recycled as bottom side emission by locating a mirror proximate to the top side of the quantum dot, as shown in FIG. 16. An example mirror may be arranged to substantially overlie the entire quantum dot but overlie only a portion of the projected area of the reflector and thus not block a substantial portion of the collimated light emanating from the reflector. Collimated top and bottom side emission from a quantum dot resulting from a top side excitation source is depicted in FIG. 17.

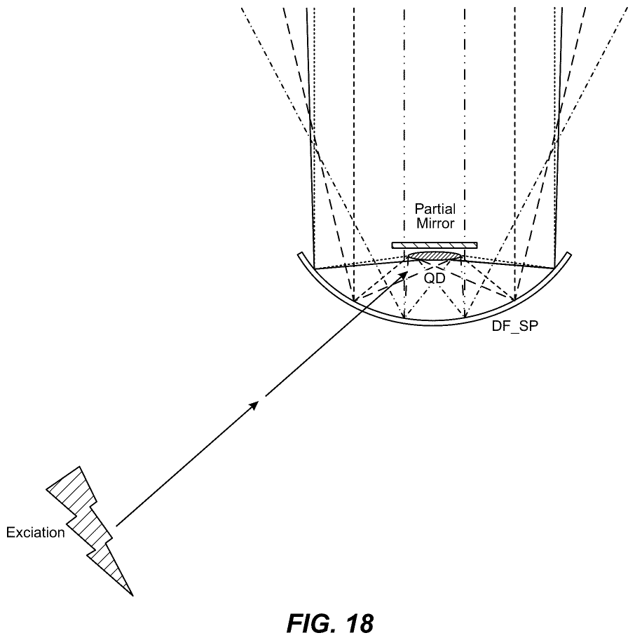

According to further embodiments, collimated top and bottom side emission from a quantum dot resulting from a bottom side excitation source is depicted in FIG. 18. In some instantiations, it may be advantageous to locate the excitation source remotely with respect to the path of the collimated bundle of emitted light. In the embodiment of FIG. 18, a short pass dichroic filter co-integrated with a curved reflector may be located proximate to a bottom side of the quantum dot and adjacent to the excitation source. The short pass dichroic filter may be configured to transmit short wavelengths (e.g., blue and/or ultraviolet light) but reflect longer wavelengths (e.g., red and/or green light).

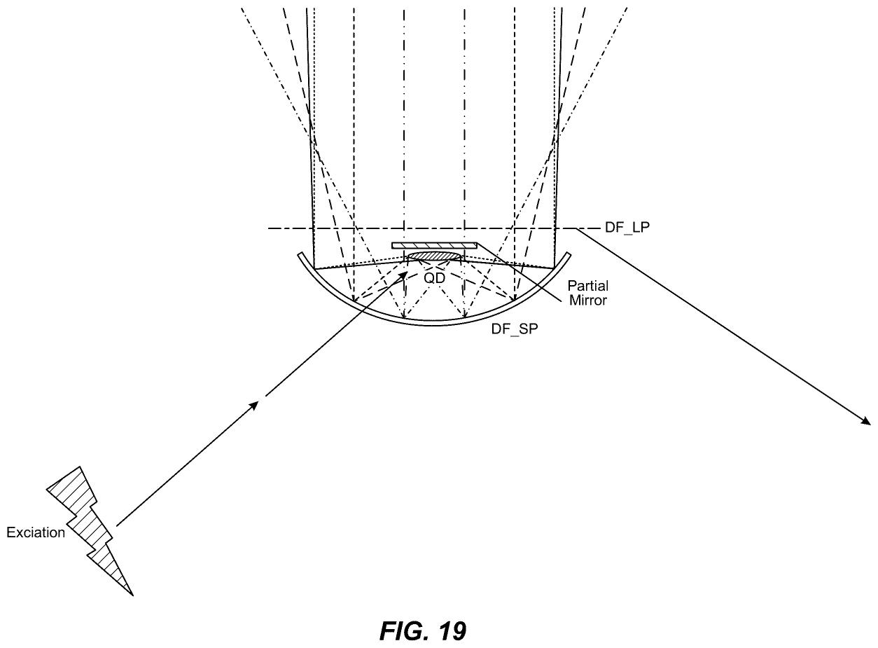

As shown in FIG. 19, a system may include a long pass dichroic filter where such a filter may be located proximate to a top side of the quantum dot (i.e., opposing the short pass dichroic filter). The long pass dichroic filter may be configured to transmit long wavelengths (e.g., red and/or green light) but reflect shorter wavelengths (e.g., blue and/or ultraviolet light). In the system of FIG. 19, blue excitation light from a bottom side excitation source may pass through the short pass dichroic filter but may be reflected by the long pass dichroic filter and therefore may be eliminated from the collimated light bundle emanating from the quantum dot, thus improving system efficiency.

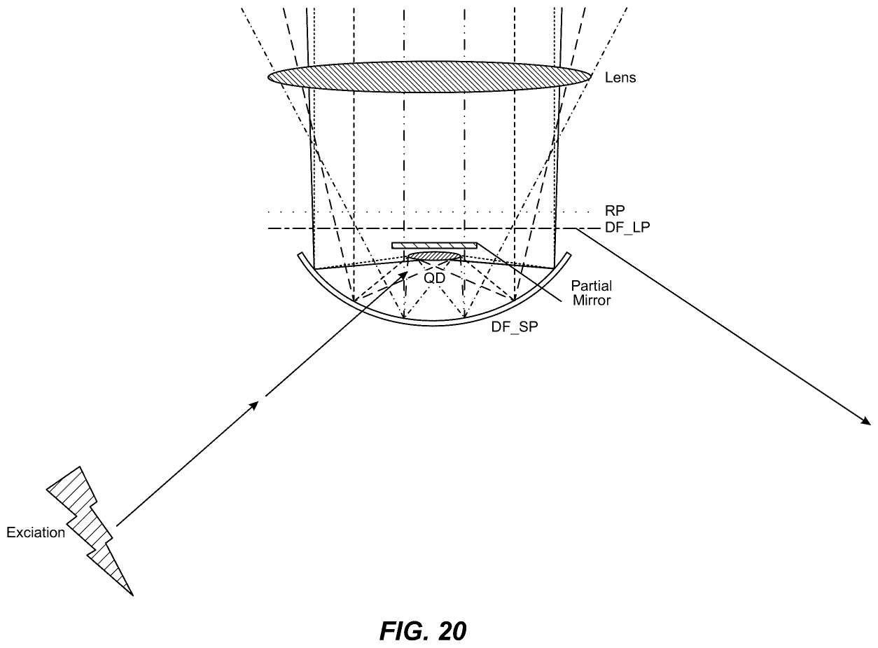

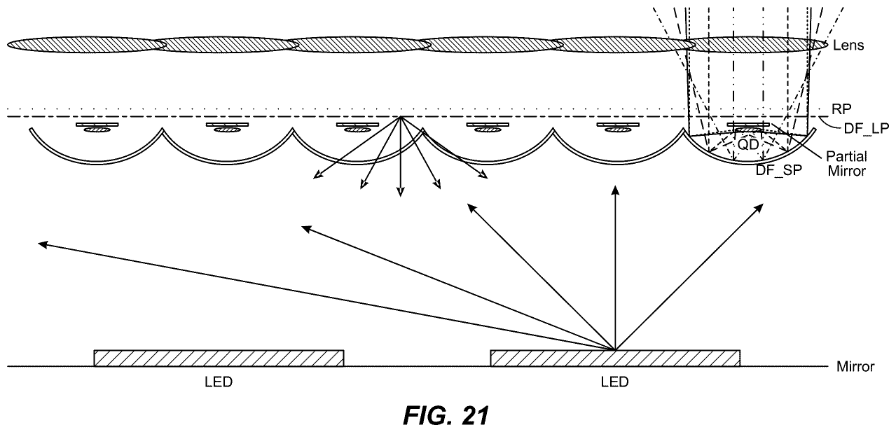

According to further embodiments, a system may include one or more additional optical elements. Referring to FIG. 20, a reflective polarizer configured to transmit one incident polarization and reflect an orthogonal polarization may be located proximate to the long pass dichroic filter of FIG. 19, and a lens configured to direct the collimated light bundle may be located proximate to the reflective polarizer.

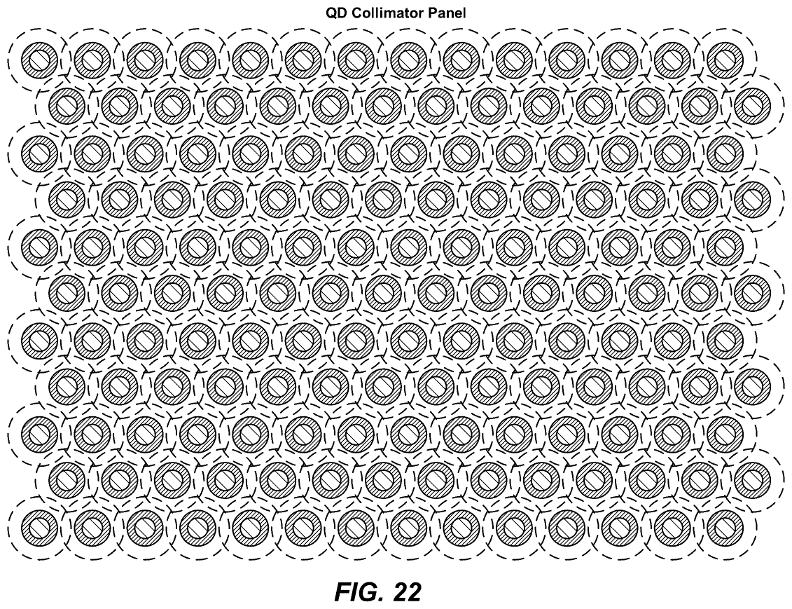

An example device is shown in FIG. 21. The device of FIG. 21 includes an array of excitation sources and a complementary array of quantum dots. The excitation sources may be configured to stimulate selected quantum dots and accordingly provide local or global emission of one or more collimated light bundles. Referring to FIG. 22, shown is a top-down plan view image of the quantum dot array (quantum dot collimator panel) for the device of FIG. 21.

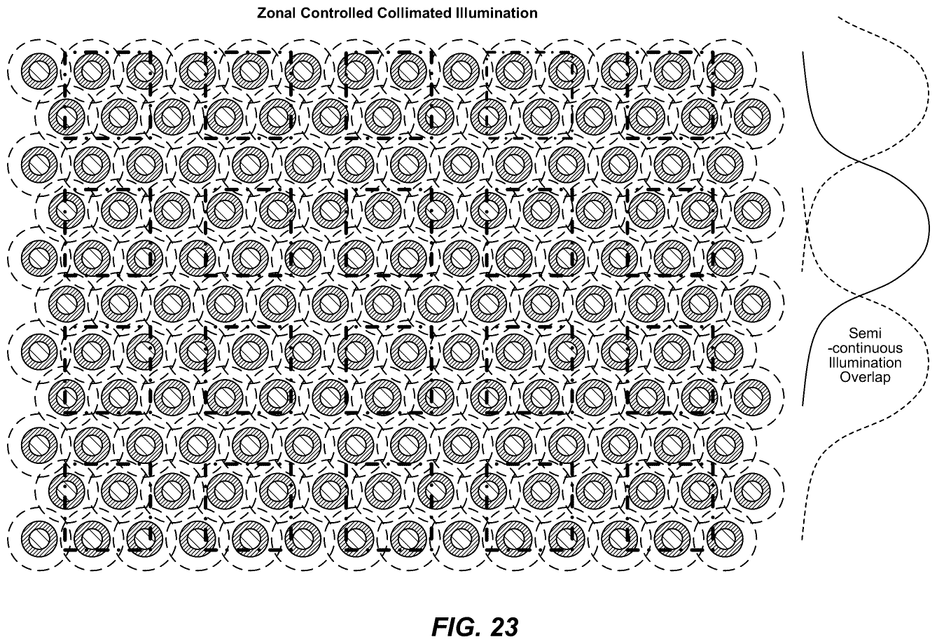

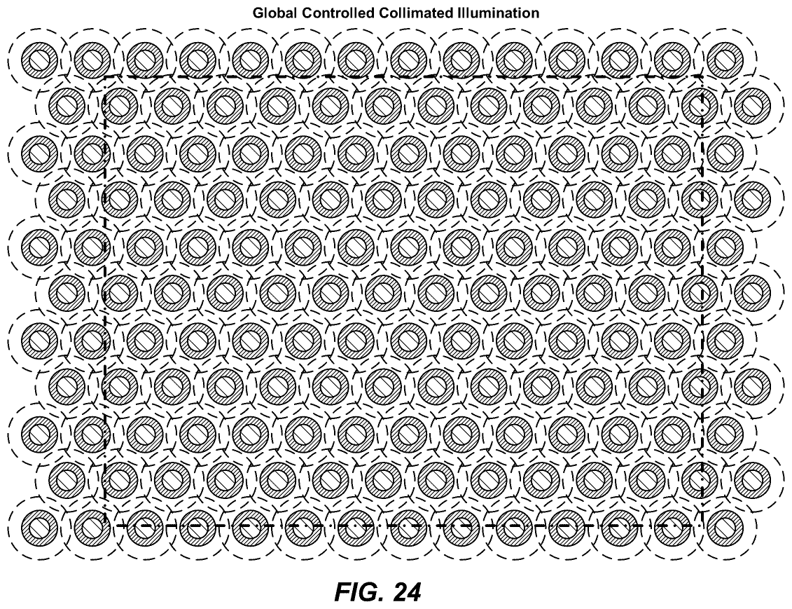

Depicted in FIGS. 23 and 24 are top-down plan view images of exemplary collimated illumination panels showing both the quantum dot array and an array of plural emitters (FIG. 23) or a single global emitter (FIG. 24). In certain embodiments, the geometry of the illumination panel may be configured to achieve a desired illumination output.

In accordance with various embodiments, a collimated illumination panel may be arranged to decouple an excitation light emission geometry with respect to a desired output color and emission geometry, such as the generation of red collimated light.

### EXAMPLE EMBODIMENTS

Example 1: A polarizing illuminator includes a light source, a collimator for collimating a light beam emitted by the light source, a parallel plate having a first surface and a second surface disposed at an acute angle with respect to the light beam, the first surface including a transmissive portion and a reflective portion and the second surface including a reflective polarizer configured to reflect one polarization of the light beam, transmit an orthogonal polarization of the light beam, and split the light beam into first and second orthogonally polarized sub-beams, and a retarding wave plate disposed between the reflective portion of the first surface and the reflective polarizer, where the retarding wave plate is configured to rotate at least one of the first sub-beam and the second sub-beam to a matched polarization, and the first and second sub-beams having the matched polarization propagate parallel to each other.

Example 2: The polarizing illuminator of Example 1, where the light source is configured to emit an unpolarized light beam.

Example 3: The polarizing illuminator of any of Examples 1 and 2, where the light source includes a linear array of light emitting diodes.

Example 4: The polarizing illuminator of any of Examples 1-3, further including a second collimator configured to focus the first and second sub-beams to a common location.

Example 5: The polarizing illuminator of any of Examples 1-4, where the reflective portion of the first surface includes a dielectric thin film stack or a reflective metal.

Example 6: The polarizing illuminator of any of Examples 1-5, where a spacing between the transmission portion of the first surface and the reflective portion of the first surface is less than approximately 0.1 mm.

Example 7: The polarizing illuminator of any of Examples 1-6, where the reflective polarizer includes a structure selected from a dielectric thin film stack, a wire grid polarizer, and a stack of birefringent films.

Example 8: The polarizing illuminator of any of Examples 1-7, where the retarding waveplate includes a quarter-wave retarder disposed over the first surface.

Example 9: The polarizing illuminator of any of Examples 1-7, where the retarding waveplate includes a quarter-wave retarder disposed over the second surface.

Example 10: An image projector coupled to a spatial light modulator (SLM) for forming image light when illuminated by the polarizing illuminator according to any of Examples 1-9.

Example 11: A method includes collimating unpolarized light emitted by a light source to obtain a collimated beam, using a tilted plate supporting spaced apart full and polarization-selective reflectors to split the collimated beam into first and second orthogonally polarized sub-beams, using a retarding waveplate to rotate a polarization of at least one of the first sub-beam and the second sub-beam to a matched polarization, where the first and second sub-beams propagate parallel to one another, and focusing the first and second sub-beams.

Example 12: The method of Example 11, further including collimating unpolarized light of a laterally extending array of light sources including the light source, using the tilted plate to split the collimated beam emitted by each light source into first and second orthogonally polarized sub-beams, and rotating a polarization of at least one of the first sub-beam and the second sub-beam to the matched polarization.

Example 13: A display lighting system includes an ultraviolet (UV) light source, a color-conversion layer that converts UV light from the UV light source to visible light, a reflective filter disposed between the UV light source and the color-conversion layer, where the reflective filter reflects the visible light and permits passage of the UV light, and a reflective polarizer that permits passage of the visible light that is in a particular polarization state and reflects other light.

Example 14: The display lighting system of Example 13, where the color conversion layer includes an array of quantum dots.

Example 15: The display lighting system of any of Examples 13 and 14, where the reflective polarizer includes a nano-wire grid.

Example 16: The display lighting system of any of Examples 13-15, further including a UV pass filter between the light source and the reflective filter.

Example 17: The display lighting system of any of Examples 13-16, further including an additional reflective filter between the color-conversion layer and the reflective polarizer.

Example 18: The display lighting system of any of Examples 13-17, further including a UV filter between the color conversion layer and the reflective polarizer.

Example 19: The display lighting system of any of Examples 13-18, further including an additional reflective filter between the color-conversion layer and the UV filter.

Example 20: The display lighting system of any of Examples 13-19, where the system is configured to output visible light.

Embodiments of the present disclosure may include or be implemented in conjunction with various types of artificial-reality systems. Artificial reality is a form of reality that has been adjusted in some manner before presentation to a user, which may include, for example, a virtual reality, an augmented reality, a mixed reality, a hybrid reality, or some combination and/or derivative thereof. Artificial-reality content may include completely computer-generated content or computer-generated content combined with captured (e.g., real-world) content. The artificial-reality content may include video, audio, haptic feedback, or some combination thereof, any of which may be presented in a single channel or in multiple channels (such as stereo video that produces a three-dimensional (3D) effect to the viewer). Additionally, in some embodiments, artificial reality may also be associated with applications, products, accessories, services, or some combination thereof, that are used to, for example, create content in an artificial reality and/or are otherwise used in (e.g., to perform activities in) an artificial reality.

Artificial-reality systems may be implemented in a variety of different form factors and configurations. Some artificial-reality systems may be designed to work without near-eye displays (NEDs). Other artificial-reality systems may include an NED that also provides visibility into the real world (such as, e.g., augmented-reality system 2500 in FIG. 25) or that visually immerses a user in an artificial reality (such as, e.g., virtual-reality system 2600 in FIG. 26). While some artificial-reality devices may be self-contained systems, other artificial-reality devices may communicate and/or coordinate with external devices to provide an artificial-reality experience to a user. Examples of such external devices include handheld controllers, mobile devices, desktop computers, devices worn by a user, devices worn by one or more other users, and/or any other suitable external system.

Turning to FIG. 25, augmented-reality system 2500 may include an eyewear device 2502 with a frame 2510 configured to hold a left display device 2515(A) and a right display device 2515(B) in front of a user's eyes. Display devices 2515(A) and 2515(B) may act together or independently to present an image or series of images to a user. While augmented-reality system 2500 includes two displays, embodiments of this disclosure may be implemented in augmented-reality systems with a single NED or more than two NEDs.

In some embodiments, augmented-reality system 2500 may include one or more sensors, such as sensor 2540. Sensor 2540 may generate measurement signals in response to motion of augmented-reality system 2500 and may be located on substantially any portion of frame 2510. Sensor 2540 may represent one or more of a variety of different sensing mechanisms, such as a position sensor, an inertial measurement unit (IMU), a depth camera assembly, a structured light emitter and/or detector, or any combination thereof. In some embodiments, augmented-reality system 2500 may or may not include sensor 2540 or may include more than one sensor. In embodiments in which sensor 2540 includes an IMU, the IMU may generate calibration data based on measurement signals from sensor 2540. Examples of sensor 2540 may include, without limitation, accelerometers, gyroscopes, magnetometers, other suitable types of sensors that detect motion, sensors used for error correction of the IMU, or some combination thereof.

In some examples, augmented-reality system 2500 may also include a microphone array with a plurality of acoustic transducers 2520(A)-2520(J), referred to collectively as acoustic transducers 2520. Acoustic transducers 2520 may represent transducers that detect air pressure variations induced by sound waves. Each acoustic transducer 2520 may be configured to detect sound and convert the detected sound into an electronic format (e.g., an analog or digital format). The microphone array in FIG. 25 may include, for example, ten acoustic transducers: 2520(A) and 2520(B), which may be designed to be placed inside a corresponding ear of the user, acoustic transducers 2520(C), 2520(D), 2520(E), 2520(F), 2520(G), and 2520(H), which may be positioned at various locations on frame 2510, and/or acoustic transducers 2520(I) and 2520(J), which may be positioned on a corresponding neckband 2505.

In some embodiments, one or more of acoustic transducers 2520(A)-(J) may be used as output transducers (e.g., speakers). For example, acoustic transducers 2520(A) and/or 2520(B) may be earbuds or any other suitable type of headphone or speaker.

The configuration of acoustic transducers 2520 of the microphone array may vary. While augmented-reality system 2500 is shown in FIG. 25 as having ten acoustic transducers 2520, the number of acoustic transducers 2520 may be greater or less than ten. In some embodiments, using higher numbers of acoustic transducers 2520 may increase the amount of audio information collected and/or the sensitivity and accuracy of the audio information. In contrast, using a lower number of acoustic transducers 2520 may decrease the computing power required by an associated controller 2550 to process the collected audio information. In addition, the position of each acoustic transducer 2520 of the microphone array may vary. For example, the position of an acoustic transducer 2520 may include a defined position on the user, a defined coordinate on frame 2510, an orientation associated with each acoustic transducer 2520, or some combination thereof.

Acoustic transducers 2520(A) and 2520(B) may be positioned on different parts of the user's ear, such as behind the pinna, behind the tragus, and/or within the auricle or fossa. Or, there may be additional acoustic transducers 2520 on or surrounding the ear in addition to acoustic transducers 2520 inside the ear canal. Having an acoustic transducer 2520 positioned next to an ear canal of a user may enable the microphone array to collect information on how sounds arrive at the ear canal. By positioning at least two of acoustic transducers 2520 on either side of a user's head (e.g., as binaural microphones), augmented-reality device 2500 may simulate binaural hearing and capture a 3D stereo sound field around about a user's head. In some embodiments, acoustic transducers 2520(A) and 2520(B) may be connected to augmented-reality system 2500 via a wired connection 2530, and in other embodiments acoustic transducers 2520(A) and 2520(B) may be connected to augmented-reality system 2500 via a wireless connection (e.g., a BLUETOOTH connection). In still other embodiments, acoustic transducers 2520(A) and 2520(B) may not be used at all in conjunction with augmented-reality system 2500.

Acoustic transducers 2520 on frame 2510 may be positioned in a variety of different ways, including along the length of the temples, across the bridge, above or below display devices 2515(A) and 2515(B), or some combination thereof. Acoustic transducers 2520 may also be oriented such that the microphone array is able to detect sounds in a wide range of directions surrounding the user wearing the augmented-reality system 2500. In some embodiments, an optimization process may be performed during manufacturing of augmented-reality system 2500 to determine relative positioning of each acoustic transducer 2520 in the microphone array.

In some examples, augmented-reality system 2500 may include or be connected to an external device (e.g., a paired device), such as neckband 2505. Neckband 2505 generally represents any type or form of paired device. Thus, the following discussion of neckband 2505 may also apply to various other paired devices, such as charging cases, smart watches, smart phones, wrist bands, other wearable devices, hand-held controllers, tablet computers, laptop computers, other external compute devices, etc.

As shown, neckband 2505 may be coupled to eyewear device 2502 via one or more connectors. The connectors may be wired or wireless and may include electrical and/or non-electrical (e.g., structural) components. In some cases, eyewear device 2502 and neckband 2505 may operate independently without any wired or wireless connection between them. While FIG. 25 illustrates the components of eyewear device 2502 and neckband 2505 in example locations on eyewear device 2502 and neckband 2505, the components may be located elsewhere and/or distributed differently on eyewear device 2502 and/or neckband 2505. In some embodiments, the components of eyewear device 2502 and neckband 2505 may be located on one or more additional peripheral devices paired with eyewear device 2502, neckband 2505, or some combination thereof.

Pairing external devices, such as neckband 2505, with augmented-reality eyewear devices may enable the eyewear devices to achieve the form factor of a pair of glasses while still providing sufficient battery and computation power for expanded capabilities. Some or all of the battery power, computational resources, and/or additional features of augmented-reality system 2500 may be provided by a paired device or shared between a paired device and an eyewear device, thus reducing the weight, heat profile, and form factor of the eyewear device overall while still retaining desired functionality. For example, neckband 2505 may allow components that would otherwise be included on an eyewear device to be included in neckband 2505 since users may tolerate a heavier weight load on their shoulders than they would tolerate on their heads. Neckband 2505 may also have a larger surface area over which to diffuse and disperse heat to the ambient environment. Thus, neckband 2505 may allow for greater battery and computation capacity than might otherwise have been possible on a stand-alone eyewear device. Since weight carried in neckband 2505 may be less invasive to a user than weight carried in eyewear device 2502, a user may tolerate wearing a lighter eyewear device and carrying or wearing the paired device for greater lengths of time than a user would tolerate wearing a heavy standalone eyewear device, thereby enabling users to more fully incorporate artificial-reality environments into their day-to-day activities.

Neckband 2505 may be communicatively coupled with eyewear device 2502 and/or to other devices. These other devices may provide certain functions (e.g., tracking, localizing, depth mapping, processing, storage, etc.) to augmented-reality system 2500. In the embodiment of FIG. 25, neckband 2505 may include two acoustic transducers (e.g., 2520(I) and 2520(J)) that are part of the microphone array (or potentially form their own microphone subarray). Neckband 2505 may also include a controller 2525 and a power source 2535.

Acoustic transducers 2520(I) and 2520(J) of neckband 2505 may be configured to detect sound and convert the detected sound into an electronic format (analog or digital). In the embodiment of FIG. 25, acoustic transducers 2520(I) and 2520(J) may be positioned on neckband 2505, thereby increasing the distance between the neckband acoustic transducers 2520(I) and 2520(J) and other acoustic transducers 2520 positioned on eyewear device 2502. In some cases, increasing the distance between acoustic transducers 2520 of the microphone array may improve the accuracy of beamforming performed via the microphone array. For example, if a sound is detected by acoustic transducers 2520(C) and 2520(D) and the distance between acoustic transducers 2520(C) and 2520(D) is greater than, e.g., the distance between acoustic transducers 2520(D) and 2520(E), the determined source location of the detected sound may be more accurate than if the sound had been detected by acoustic transducers 2520(D) and 2520(E).

Controller 2525 of neckband 2505 may process information generated by the sensors on neckband 2505 and/or augmented-reality system 2500. For example, controller 2525 may process information from the microphone array that describes sounds detected by the microphone array. For each detected sound, controller 2525 may perform a direction-of-arrival (DOA) estimation to estimate a direction from which the detected sound arrived at the microphone array. As the microphone array detects sounds, controller 2525 may populate an audio data set with the information. In embodiments in which augmented-reality system 2500 includes an inertial measurement unit, controller 2525 may compute all inertial and spatial calculations from the IMU located on eyewear device 2502. A connector may convey information between augmented-reality system 2500 and neckband 2505 and between augmented-reality system 2500 and controller 2525. The information may be in the form of optical data, electrical data, wireless data, or any other transmittable data form. Moving the processing of information generated by augmented-reality system 2500 to neckband 2505 may reduce weight and heat in eyewear device 2502, making it more comfortable to the user.

Power source 2535 in neckband 2505 may provide power to eyewear device 2502 and/or to neckband 2505. Power source 2535 may include, without limitation, lithium ion batteries, lithium-polymer batteries, primary lithium batteries, alkaline batteries, or any other form of power storage. In some cases, power source 2535 may be a wired power source. Including power source 2535 on neckband 2505 instead of on eyewear device 2502 may help better distribute the weight and heat generated by power source 2535.

As noted, some artificial-reality systems may, instead of blending an artificial reality with actual reality, substantially replace one or more of a user's sensory perceptions of the real world with a virtual experience. One example of this type of system is a head-worn display system, such as virtual-reality system 2600 in FIG. 26, that mostly or completely covers a user's field of view. Virtual-reality system 2600 may include a front rigid body 2602 and a band 2604 shaped to fit around a user's head. Virtual-reality system 2600 may also include output audio transducers 2606(A) and 2606(B). Furthermore, while not shown in FIG. 26, front rigid body 2602 may include one or more electronic elements, including one or more electronic displays, one or more inertial measurement units (IMUs), one or more tracking emitters or detectors, and/or any other suitable device or system for creating an artificial-reality experience.

Artificial-reality systems may include a variety of types of visual feedback mechanisms. For example, display devices in augmented-reality system 2500 and/or virtual-reality system 2600 may include one or more liquid crystal displays (LCDs), light emitting diode (LED) displays, microLED displays, organic LED (OLED) displays, digital light project (DLP) micro-displays, liquid crystal on silicon (LCoS) micro-displays, and/or any other suitable type of display screen. These artificial-reality systems may include a single display screen for both eyes or may provide a display screen for each eye, which may allow for additional flexibility for varifocal adjustments or for correcting a user's refractive error. Some of these artificial-reality systems may also include optical subsystems having one or more lenses (e.g., concave or convex lenses, Fresnel lenses, adjustable liquid lenses, etc.) through which a user may view a display screen. These optical subsystems may serve a variety of purposes, including to collimate (e.g., make an object appear at a greater distance than its physical distance), to magnify (e.g., make an object appear larger than its actual size), and/or to relay (to, e.g., the viewer's eyes) light. These optical subsystems may be used in a non-pupil-forming architecture (such as a single lens configuration that directly collimates light but results in so-called pincushion distortion) and/or a pupil-forming architecture (such as a multi-lens configuration that produces so-called barrel distortion to nullify pincushion distortion).

In addition to or instead of using display screens, some of the artificial-reality systems described herein may include one or more projection systems. For example, display devices in augmented-reality system 2500 and/or virtual-reality system 2600 may include micro-LED projectors that project light (using, e.g., a waveguide) into display devices, such as clear combiner lenses that allow ambient light to pass through. The display devices may refract the projected light toward a user's pupil and may enable a user to simultaneously view both artificial-reality content and the real world. The display devices may accomplish this using any of a variety of different optical components, including waveguide components (e.g., holographic, planar, diffractive, polarized, and/or reflective waveguide elements), light-manipulation surfaces and elements (such as diffractive, reflective, and refractive elements and gratings), coupling elements, etc. Artificial-reality systems may also be configured with any other suitable type or form of image projection system, such as retinal projectors used in virtual retina displays.

The artificial-reality systems described herein may also include various types of computer vision components and subsystems. For example, augmented-reality system 2500 and/or virtual-reality system 2600 may include one or more optical sensors, such as two-dimensional (2D) or 3D cameras, structured light transmitters and detectors, time-of-flight depth sensors, single-beam or sweeping laser rangefinders, 3D LiDAR sensors, and/or any other suitable type or form of optical sensor. An artificial-reality system may process data from one or more of these sensors to identify a location of a user, to map the real world, to provide a user with context about real-world surroundings, and/or to perform a variety of other functions.

The artificial-reality systems described herein may also include one or more input and/or output audio transducers. Output audio transducers may include voice coil speakers, ribbon speakers, electrostatic speakers, piezoelectric speakers, bone conduction transducers, cartilage conduction transducers, tragus-vibration transducers, and/or any other suitable type or form of audio transducer. Similarly, input audio transducers may include condenser microphones, dynamic microphones, ribbon microphones, and/or any other type or form of input transducer. In some embodiments, a single transducer may be used for both audio input and audio output.

In some embodiments, the artificial-reality systems described herein may also include tactile (i.e., haptic) feedback systems, which may be incorporated into headwear, gloves, body suits, handheld controllers, environmental devices (e.g., chairs, floormats, etc.), and/or any other type of device or system. Haptic feedback systems may provide various types of cutaneous feedback, including vibration, force, traction, texture, and/or temperature. Haptic feedback systems may also provide various types of kinesthetic feedback, such as motion and compliance. Haptic feedback may be implemented using motors, piezoelectric actuators, fluidic systems, and/or a variety of other types of feedback mechanisms. Haptic feedback systems may be implemented independent of other artificial-reality devices, within other artificial-reality devices, and/or in conjunction with other artificial-reality devices.

By providing haptic sensations, audible content, and/or visual content, artificial-reality systems may create an entire virtual experience or enhance a user's real-world experience in a variety of contexts and environments. For instance, artificial-reality systems may assist or extend a user's perception, memory, or cognition within a particular environment. Some systems may enhance a user's interactions with other people in the real world or may enable more immersive interactions with other people in a virtual world. Artificial-reality systems may also be used for educational purposes (e.g., for teaching or training in schools, hospitals, government organizations, military organizations, business enterprises, etc.), entertainment purposes (e.g., for playing video games, listening to music, watching video content, etc.), and/or for accessibility purposes (e.g., as hearing aids, visual aids, etc.). The embodiments disclosed herein may enable or enhance a user's artificial-reality experience in one or more of these contexts and environments and/or in other contexts and environments.

Some augmented-reality systems may map a user's and/or device's environment using techniques referred to as “simultaneous location and mapping” (SLAM). SLAM mapping and location identifying techniques may involve a variety of hardware and software tools that can create or update a map of an environment while simultaneously keeping track of a user's location within the mapped environment. SLAM may use many different types of sensors to create a map and determine a user's position within the map.

SLAM techniques may, for example, implement optical sensors to determine a user's location. Radios including WiFi, BLUETOOTH, global positioning system (GPS), cellular or other communication devices may be also used to determine a user's location relative to a radio transceiver or group of transceivers (e.g., a WiFi router or group of GPS satellites). Acoustic sensors such as microphone arrays or 2D or 3D sonar sensors may also be used to determine a user's location within an environment. Augmented-reality and virtual-reality devices (such as systems 2500 and 2600 of FIGS. 25 and 26, respectively) may incorporate any or all of these types of sensors to perform SLAM operations such as creating and continually updating maps of the user's current environment. In at least some of the embodiments described herein, SLAM data generated by these sensors may be referred to as “environmental data” and may indicate a user's current environment. This data may be stored in a local or remote data store (e.g., a cloud data store) and may be provided to a user's AR/VR device on demand.

When the user is wearing an augmented-reality headset or virtual-reality headset in a given environment, the user may be interacting with other users or other electronic devices that serve as audio sources. In some cases, it may be desirable to determine where the audio sources are located relative to the user and then present the audio sources to the user as if they were coming from the location of the audio source. The process of determining where the audio sources are located relative to the user may be referred to as “localization,” and the process of rendering playback of the audio source signal to appear as if it is coming from a specific direction may be referred to as “spatialization.”

Localizing an audio source may be performed in a variety of different ways. In some cases, an augmented-reality or virtual-reality headset may initiate a DOA analysis to determine the location of a sound source. The DOA analysis may include analyzing the intensity, spectra, and/or arrival time of each sound at the artificial-reality device to determine the direction from which the sounds originated. The DOA analysis may include any suitable algorithm for analyzing the surrounding acoustic environment in which the artificial-reality device is located.

For example, the DOA analysis may be designed to receive input signals from a microphone and apply digital signal processing algorithms to the input signals to estimate the direction of arrival. These algorithms may include, for example, delay and sum algorithms where the input signal is sampled, and the resulting weighted and delayed versions of the sampled signal are averaged together to determine a direction of arrival. A least mean squared (LMS) algorithm may also be implemented to create an adaptive filter. This adaptive filter may then be used to identify differences in signal intensity, for example, or differences in time of arrival. These differences may then be used to estimate the direction of arrival. In another embodiment, the DOA may be determined by converting the input signals into the frequency domain and selecting specific bins within the time-frequency (TF) domain to process. Each selected TF bin may be processed to determine whether that bin includes a portion of the audio spectrum with a direct-path audio signal. Those bins having a portion of the direct-path signal may then be analyzed to identify the angle at which a microphone array received the direct-path audio signal. The determined angle may then be used to identify the direction of arrival for the received input signal. Other algorithms not listed above may also be used alone or in combination with the above algorithms to determine DOA.

In some embodiments, different users may perceive the source of a sound as coming from slightly different locations. This may be the result of each user having a unique head-related transfer function (HRTF), which may be dictated by a user's anatomy including ear canal length and the positioning of the ear drum. The artificial-reality device may provide an alignment and orientation guide, which the user may follow to customize the sound signal presented to the user based on their unique HRTF. In some embodiments, an artificial-reality device may implement one or more microphones to listen to sounds within the user's environment. The augmented-reality or virtual-reality headset may use a variety of different array transfer functions (e.g., any of the DOA algorithms identified above) to estimate the direction of arrival for the sounds. Once the direction of arrival has been determined, the artificial-reality device may play back sounds to the user according to the user's unique HRTF. Accordingly, the DOA estimation generated using the array transfer function (ATF) may be used to determine the direction from which the sounds are to be played from. The playback sounds may be further refined based on how that specific user hears sounds according to the HRTF.

In addition to or as an alternative to performing a DOA estimation, an artificial-reality device may perform localization based on information received from other types of sensors. These sensors may include cameras, IR sensors, heat sensors, motion sensors, GPS receivers, or in some cases, sensors that detect a user's eye movements. For example, as noted above, an artificial-reality device may include an eye tracker or gaze detector that determines where the user is looking. Often, the user's eyes will look at the source of the sound, if only briefly. Such clues provided by the user's eyes may further aid in determining the location of a sound source. Other sensors such as cameras, heat sensors, and IR sensors may also indicate the location of a user, the location of an electronic device, or the location of another sound source. Any or all of the above methods may be used individually or in combination to determine the location of a sound source and may further be used to update the location of a sound source over time.

Some embodiments may implement the determined DOA to generate a more customized output audio signal for the user. For instance, an “acoustic transfer function” may characterize or define how a sound is received from a given location. More specifically, an acoustic transfer function may define the relationship between parameters of a sound at its source location and the parameters by which the sound signal is detected (e.g., detected by a microphone array or detected by a user's ear). An artificial-reality device may include one or more acoustic sensors that detect sounds within range of the device. A controller of the artificial-reality device may estimate a DOA for the detected sounds (using, e.g., any of the methods identified above) and, based on the parameters of the detected sounds, may generate an acoustic transfer function that is specific to the location of the device. This customized acoustic transfer function may thus be used to generate a spatialized output audio signal where the sound is perceived as coming from a specific location.

Indeed, once the location of the sound source or sources is known, the artificial-reality device may re-render (i.e., spatialize) the sound signals to sound as if coming from the direction of that sound source. The artificial-reality device may apply filters or other digital signal processing that alter the intensity, spectra, or arrival time of the sound signal. The digital signal processing may be applied in such a way that the sound signal is perceived as originating from the determined location. The artificial-reality device may amplify or subdue certain frequencies or change the time that the signal arrives at each ear. In some cases, the artificial-reality device may create an acoustic transfer function that is specific to the location of the device and the detected direction of arrival of the sound signal. In some embodiments, the artificial-reality device may re-render the source signal in a stereo device or multi-speaker device (e.g., a surround sound device). In such cases, separate and distinct audio signals may be sent to each speaker. Each of these audio signals may be altered according to the user's HRTF and according to measurements of the user's location and the location of the sound source to sound as if they are coming from the determined location of the sound source. Accordingly, in this manner, the artificial-reality device (or speakers associated with the device) may re-render an audio signal to sound as if originating from a specific location.

As noted, artificial-reality systems 2500 and 2600 may be used with a variety of other types of devices to provide a more compelling artificial-reality experience. These devices may be haptic interfaces with transducers that provide haptic feedback and/or that collect haptic information about a user's interaction with an environment. The artificial-reality systems disclosed herein may include various types of haptic interfaces that detect or convey various types of haptic information, including tactile feedback (e.g., feedback that a user detects via nerves in the skin, which may also be referred to as cutaneous feedback) and/or kinesthetic feedback (e.g., feedback that a user detects via receptors located in muscles, joints, and/or tendons).

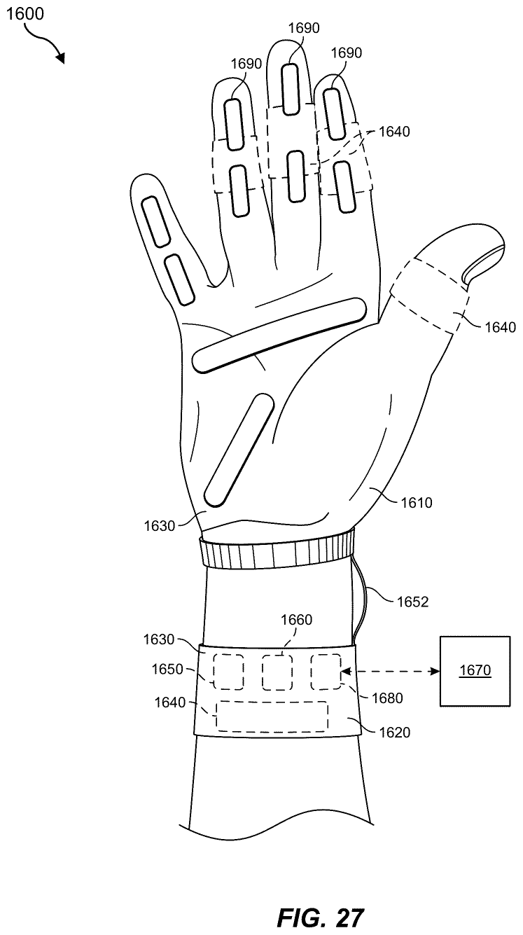

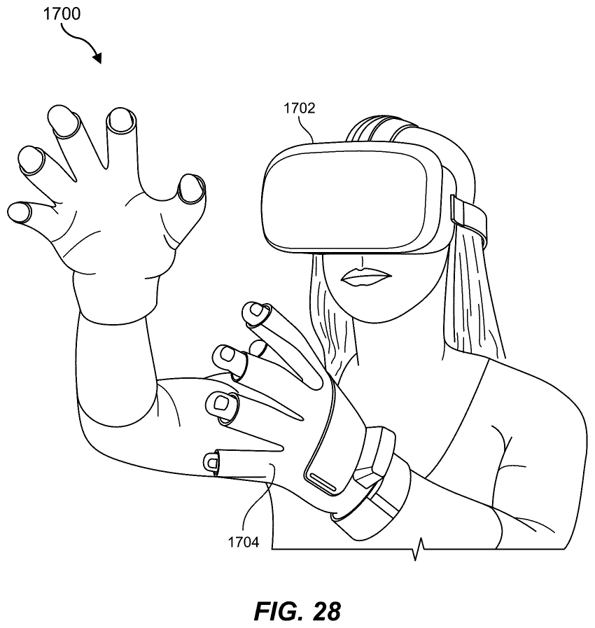

Haptic feedback may be provided by interfaces positioned within a user's environment (e.g., chairs, tables, floors, etc.) and/or interfaces on articles that may be worn or carried by a user (e.g., gloves, wristbands, etc.). As an example, FIG. 27 illustrates a vibrotactile system 2700 in the form of a wearable glove (haptic device 2710) and wristband (haptic device 2720). Haptic device 2710 and haptic device 2720 are shown as examples of wearable devices that include a flexible, wearable textile material 2730 that is shaped and configured for positioning against a user's hand and wrist, respectively. This disclosure also includes vibrotactile systems that may be shaped and configured for positioning against other human body parts, such as a finger, an arm, a head, a torso, a foot, or a leg. By way of example and not limitation, vibrotactile systems according to various embodiments of the present disclosure may also be in the form of a glove, a headband, an armband, a sleeve, a head covering, a sock, a shirt, or pants, among other possibilities. In some examples, the term “textile” may include any flexible, wearable material, including woven fabric, non-woven fabric, leather, cloth, a flexible polymer material, composite materials, etc.

One or more vibrotactile devices 2740 may be positioned at least partially within one or more corresponding pockets formed in textile material 2730 of vibrotactile system 2700. Vibrotactile devices 2740 may be positioned in locations to provide a vibrating sensation (e.g., haptic feedback) to a user of vibrotactile system 2700. For example, vibrotactile devices 2740 may be positioned against the user's finger(s), thumb, or wrist, as shown in FIG. 27. Vibrotactile devices 2740 may, in some examples, be sufficiently flexible to conform to or bend with the user's corresponding body part(s).

A power source 2750 (e.g., a battery) for applying a voltage to the vibrotactile devices 2740 for activation thereof may be electrically coupled to vibrotactile devices 2740, such as via conductive wiring 2752. In some examples, each of vibrotactile devices 2740 may be independently electrically coupled to power source 2750 for individual activation. In some embodiments, a processor 2760 may be operatively coupled to power source 2750 and configured (e.g., programmed) to control activation of vibrotactile devices 2740.

Vibrotactile system 2700 may be implemented in a variety of ways. In some examples, vibrotactile system 2700 may be a standalone system with integral subsystems and components for operation independent of other devices and systems. As another example, vibrotactile system 2700 may be configured for interaction with another device or system 2770. For example, vibrotactile system 2700 may, in some examples, include a communications interface 2780 for receiving and/or sending signals to the other device or system 2770. The other device or system 2770 may be a mobile device, a gaming console, an artificial-reality (e.g., virtual-reality, augmented-reality, mixed-reality) device, a personal computer, a tablet computer, a network device (e.g., a modem, a router, etc.), a handheld controller, etc. Communications interface 2780 may enable communications between vibrotactile system 2700 and the other device or system 2770 via a wireless (e.g., Wi-Fi, BLUETOOTH, cellular, radio, etc.) link or a wired link. If present, communications interface 2780 may be in communication with processor 2760, such as to provide a signal to processor 2760 to activate or deactivate one or more of the vibrotactile devices 2740.

Vibrotactile system 2700 may optionally include other subsystems and components, such as touch-sensitive pads 2790, pressure sensors, motion sensors, position sensors, lighting elements, and/or user interface elements (e.g., an on/off button, a vibration control element, etc.). During use, vibrotactile devices 2740 may be configured to be activated for a variety of different reasons, such as in response to the user's interaction with user interface elements, a signal from the motion or position sensors, a signal from the touch-sensitive pads 2790, a signal from the pressure sensors, a signal from the other device or system 2770, etc.

Although power source 2750, processor 2760, and communications interface 2780 are illustrated in FIG. 27 as being positioned in haptic device 2720, the present disclosure is not so limited. For example, one or more of power source 2750, processor 2760, or communications interface 2780 may be positioned within haptic device 2710 or within another wearable textile.

Haptic wearables, such as those shown in and described in connection with FIG. 27, may be implemented in a variety of types of artificial-reality systems and environments. FIG. 28 shows an example artificial-reality environment 2800 including one head-mounted virtual-reality display and two haptic devices (i.e., gloves), and in other embodiments any number and/or combination of these components and other components may be included in an artificial-reality system. For example, in some embodiments there may be multiple head-mounted displays each having an associated haptic device, with each head-mounted display and each haptic device communicating with the same console, portable computing device, or other computing system.

Head-mounted display 2802 generally represents any type or form of virtual-reality system, such as virtual-reality system 2600 in FIG. 26. Haptic device 604 generally represents any type or form of wearable device, worn by a user of an artificial-reality system, that provides haptic feedback to the user to give the user the perception that he or she is physically engaging with a virtual object. In some embodiments, haptic device 2804 may provide haptic feedback by applying vibration, motion, and/or force to the user. For example, haptic device 2804 may limit or augment a user's movement. To give a specific example, haptic device 2804 may limit a user's hand from moving forward so that the user has the perception that his or her hand has come in physical contact with a virtual wall. In this specific example, one or more actuators within the haptic device may achieve the physical-movement restriction by pumping fluid into an inflatable bladder of the haptic device. In some examples, a user may also use haptic device 2804 to send action requests to a console. Examples of action requests include, without limitation, requests to start an application and/or end the application and/or requests to perform a particular action within the application.

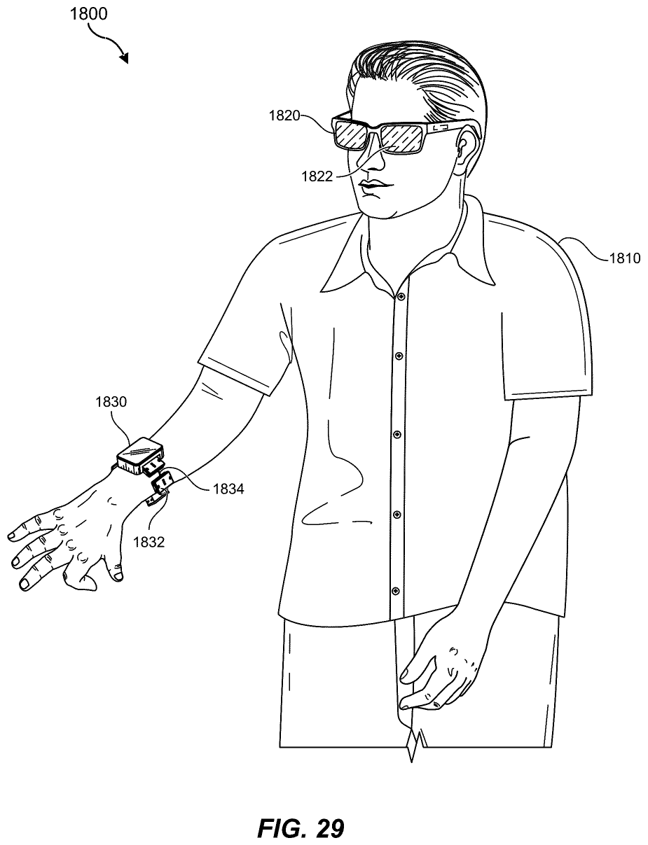

While haptic interfaces may be used with virtual-reality systems, as shown in FIG. 28, haptic interfaces may also be used with augmented-reality systems, as shown in FIG. 29. FIG. 29 is a perspective view of a user 2910 interacting with an augmented-reality system 2900. In this example, user 2910 may wear a pair of augmented-reality glasses 2920 that may have one or more displays 2922 and that are paired with a haptic device 2930. In this example, haptic device 2930 may be a wristband that includes a plurality of band elements 2932 and a tensioning mechanism 2934 that connects band elements 2932 to one another.

One or more of band elements 2932 may include any type or form of actuator suitable for providing haptic feedback. For example, one or more of band elements 2932 may be configured to provide one or more of various types of cutaneous feedback, including vibration, force, traction, texture, and/or temperature. To provide such feedback, band elements 2932 may include one or more of various types of actuators. In one example, each of band elements 2932 may include a vibrotactor (e.g., a vibrotactile actuator) configured to vibrate in unison or independently to provide one or more of various types of haptic sensations to a user. Alternatively, only a single band element or a subset of band elements may include vibrotactors.

Haptic devices 2710, 2720, 2804, and 2930 may include any suitable number and/or type of haptic transducer, sensor, and/or feedback mechanism. For example, haptic devices 2710, 2720, 2804, and 2930 may include one or more mechanical transducers, piezoelectric transducers, and/or fluidic transducers. Haptic devices 2710, 2720, 2804, and 2930 may also include various combinations of different types and forms of transducers that work together or independently to enhance a user's artificial-reality experience. In one example, each of band elements 2932 of haptic device 2930 may include a vibrotactor (e.g., a vibrotactile actuator) configured to vibrate in unison or independently to provide one or more of various types of haptic sensations to a user.

In some embodiments, the systems described herein may also include an eye-tracking subsystem designed to identify and track various characteristics of a user's eye(s), such as the user's gaze direction. The phrase “eye tracking” may, in some examples, refer to a process by which the position, orientation, and/or motion of an eye is measured, detected, sensed, determined, and/or monitored. The disclosed systems may measure the position, orientation, and/or motion of an eye in a variety of different ways, including through the use of various optical-based eye-tracking techniques, ultrasound-based eye-tracking techniques, etc. An eye-tracking subsystem may be configured in a number of different ways and may include a variety of different eye-tracking hardware components or other computer-vision components. For example, an eye-tracking subsystem may include a variety of different optical sensors, such as two-dimensional (2D) or 3D cameras, time-of-flight depth sensors, single-beam or sweeping laser rangefinders, 3D LiDAR sensors, and/or any other suitable type or form of optical sensor. In this example, a processing subsystem may process data from one or more of these sensors to measure, detect, determine, and/or otherwise monitor the position, orientation, and/or motion of the user's eye(s).

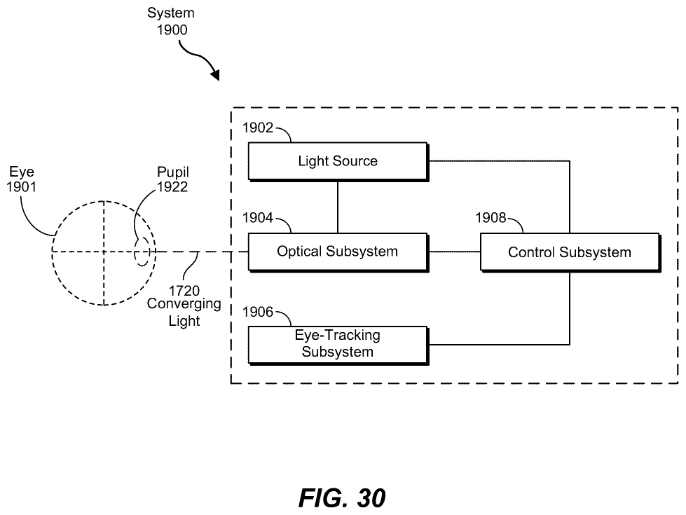

FIG. 30 is an illustration of an exemplary system 3000 that incorporates an eye-tracking subsystem capable of tracking a user's eye(s). As depicted in FIG. 30, system 3000 may include a light source 3002, an optical subsystem 3004, an eye-tracking subsystem 3006, and/or a control subsystem 3008. In some examples, light source 3002 may generate light for an image (e.g., to be presented to an eye 3001 of the viewer). Light source 3002 may represent any of a variety of suitable devices. For example, light source 3002 can include a two-dimensional projector (e.g., a LCoS display), a scanning source (e.g., a scanning laser), or other device (e.g., an LCD, an LED display, an OLED display, an active-matrix OLED display (AMOLED), a transparent OLED display (TOLED), a waveguide, or some other display capable of generating light for presenting an image to the viewer). In some examples, the image may represent a virtual image, which may refer to an optical image formed from the apparent divergence of light rays from a point in space, as opposed to an image formed from the light ray's actual divergence.

In some embodiments, optical subsystem 3004 may receive the light generated by light source 3002 and generate, based on the received light, converging light 3020 that includes the image. In some examples, optical subsystem 3004 may include any number of lenses (e.g., Fresnel lenses, convex lenses, concave lenses), apertures, filters, mirrors, prisms, and/or other optical components, possibly in combination with actuators and/or other devices. In particular, the actuators and/or other devices may translate and/or rotate one or more of the optical components to alter one or more aspects of converging light 3020. Further, various mechanical couplings may serve to maintain the relative spacing and/or the orientation of the optical components in any suitable combination.

In one embodiment, eye-tracking subsystem 3006 may generate tracking information indicating a gaze angle of an eye 3001 of the viewer. In this embodiment, control subsystem 3008 may control aspects of optical subsystem 3004 (e.g., the angle of incidence of converging light 3020) based at least in part on this tracking information. Additionally, in some examples, control subsystem 3008 may store and utilize historical tracking information (e.g., a history of the tracking information over a given duration, such as the previous second or fraction thereof) to anticipate the gaze angle of eye 3001 (e.g., an angle between the visual axis and the anatomical axis of eye 3001). In some embodiments, eye-tracking subsystem 3006 may detect radiation emanating from some portion of eye 3001 (e.g., the cornea, the iris, the pupil, or the like) to determine the current gaze angle of eye 3001. In other examples, eye-tracking subsystem 806 may employ a wavefront sensor to track the current location of the pupil.

Any number of techniques can be used to track eye 3001. Some techniques may involve illuminating eye 3001 with infrared light and measuring reflections with at least one optical sensor that is tuned to be sensitive to the infrared light. Information about how the infrared light is reflected from eye 3001 may be analyzed to determine the position(s), orientation(s), and/or motion(s) of one or more eye feature(s), such as the cornea, pupil, iris, and/or retinal blood vessels.

In some examples, the radiation captured by a sensor of eye-tracking subsystem 3006 may be digitized (i.e., converted to an electronic signal). Further, the sensor may transmit a digital representation of this electronic signal to one or more processors (for example, processors associated with a device including eye-tracking subsystem 3006). Eye-tracking subsystem 3006 may include any of a variety of sensors in a variety of different configurations. For example, eye-tracking subsystem 3006 may include an infrared detector that reacts to infrared radiation. The infrared detector may be a thermal detector, a photonic detector, and/or any other suitable type of detector. Thermal detectors may include detectors that react to thermal effects of the incident infrared radiation.

In some examples, one or more processors may process the digital representation generated by the sensor(s) of eye-tracking subsystem 3006 to track the movement of eye 3001. In another example, these processors may track the movements of eye 3001 by executing algorithms represented by computer-executable instructions stored on non-transitory memory. In some examples, on-chip logic (e.g., an application-specific integrated circuit or ASIC) may be used to perform at least portions of such algorithms. As noted, eye-tracking subsystem 3006 may be programmed to use an output of the sensor(s) to track movement of eye 3001. In some embodiments, eye-tracking subsystem 3006 may analyze the digital representation generated by the sensors to extract eye rotation information from changes in reflections. In one embodiment, eye-tracking subsystem 3006 may use corneal reflections or glints (also known as Purkinje images) and/or the center of the eye's pupil 3022 as features to track over time.

In some embodiments, eye-tracking subsystem 3006 may use the center of the eye's pupil 3022 and infrared or near-infrared, non-collimated light to create corneal reflections. In these embodiments, eye-tracking subsystem 3006 may use the vector between the center of the eye's pupil 3022 and the corneal reflections to compute the gaze direction of eye 3001. In some embodiments, the disclosed systems may perform a calibration procedure for an individual (using, e.g., supervised or unsupervised techniques) before tracking the user's eyes. For example, the calibration procedure may include directing users to look at one or more points displayed on a display while the eye-tracking system records the values that correspond to each gaze position associated with each point.

In some embodiments, eye-tracking subsystem 3006 may use two types of infrared and/or near-infrared (also known as active light) eye-tracking techniques: bright-pupil and dark-pupil eye tracking, which may be differentiated based on the location of an illumination source with respect to the optical elements used. If the illumination is coaxial with the optical path, then eye 3001 may act as a retroreflector as the light reflects off the retina, thereby creating a bright pupil effect similar to a red-eye effect in photography. If the illumination source is offset from the optical path, then the eye's pupil 3022 may appear dark because the retroreflection from the retina is directed away from the sensor. In some embodiments, bright-pupil tracking may create greater iris/pupil contrast, allowing more robust eye tracking with iris pigmentation, and may feature reduced interference (e.g., interference caused by eyelashes and other obscuring features). Bright-pupil tracking may also allow tracking in lighting conditions ranging from total darkness to a very bright environment.

In some embodiments, control subsystem 3008 may control light source 3002 and/or optical subsystem 3004 to reduce optical aberrations (e.g., chromatic aberrations and/or monochromatic aberrations) of the image that may be caused by or influenced by eye 3001. In some examples, as mentioned above, control subsystem 3008 may use the tracking information from eye-tracking subsystem 3006 to perform such control. For example, in controlling light source 3002, control subsystem 3008 may alter the light generated by light source 3002 (e.g., by way of image rendering) to modify (e.g., pre-distort) the image so that the aberration of the image caused by eye 3001 is reduced.

The disclosed systems may track both the position and relative size of the pupil (since, e.g., the pupil dilates and/or contracts). In some examples, the eye-tracking devices and components (e.g., sensors and/or sources) used for detecting and/or tracking the pupil may be different (or calibrated differently) for different types of eyes. For example, the frequency range of the sensors may be different (or separately calibrated) for eyes of different colors and/or different pupil types, sizes, and/or the like. As such, the various eye-tracking components (e.g., infrared sources and/or sensors) described herein may need to be calibrated for each individual user and/or eye.

The disclosed systems may track both eyes with and without ophthalmic correction, such as that provided by contact lenses worn by the user. In some embodiments, ophthalmic correction elements (e.g., adjustable lenses) may be directly incorporated into the artificial reality systems described herein. In some examples, the color of the user's eye may necessitate modification of a corresponding eye-tracking algorithm. For example, eye-tracking algorithms may need to be modified based at least in part on the differing color contrast between a brown eye and, for example, a blue eye.

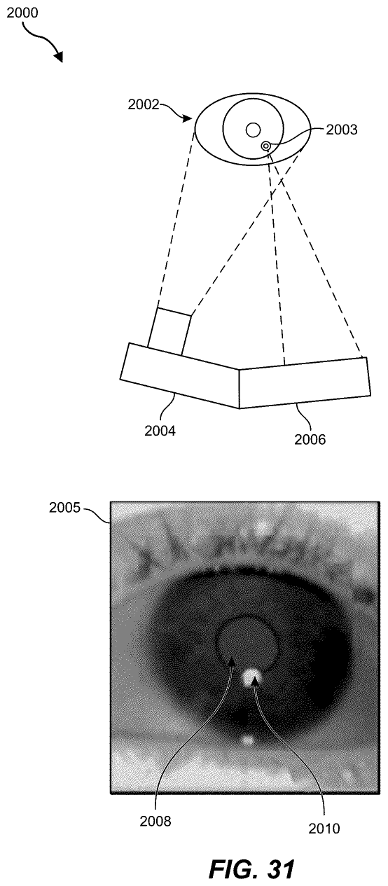

FIG. 31 is a more detailed illustration of various aspects of the eye-tracking subsystem illustrated in FIG. 30. As shown in this figure, an eye-tracking subsystem 3100 may include at least one source 3104 and at least one sensor 3106. Source 3104 generally represents any type or form of element capable of emitting radiation. In one example, source 3104 may generate visible, infrared, and/or near-infrared radiation. In some examples, source 3104 may radiate non-collimated infrared and/or near-infrared portions of the electromagnetic spectrum towards an eye 3102 of a user. Source 3104 may utilize a variety of sampling rates and speeds. For example, the disclosed systems may use sources with higher sampling rates in order to capture fixational eye movements of a user's eye 3102 and/or to correctly measure saccade dynamics of the user's eye 3102. As noted above, any type or form of eye-tracking technique may be used to track the user's eye 3102, including optical-based eye-tracking techniques, ultrasound-based eye-tracking techniques, etc.

Sensor 3106 generally represents any type or form of element capable of detecting radiation, such as radiation reflected off the user's eye 3102. Examples of sensor 3106 include, without limitation, a charge coupled device (CCD), a photodiode array, a complementary metal-oxide-semiconductor (CMOS) based sensor device, and/or the like. In one example, sensor 3106 may represent a sensor having predetermined parameters, including, but not limited to, a dynamic resolution range, linearity, and/or other characteristic selected and/or designed specifically for eye tracking.

As detailed above, eye-tracking subsystem 3100 may generate one or more glints. As detailed above, a glint 3103 may represent reflections of radiation (e.g., infrared radiation from an infrared source, such as source 3104) from the structure of the user's eye. In various embodiments, glint 3103 and/or the user's pupil may be tracked using an eye-tracking algorithm executed by a processor (either within or external to an artificial reality device). For example, an artificial reality device may include a processor and/or a memory device in order to perform eye tracking locally and/or a transceiver to send and receive the data necessary to perform eye tracking on an external device (e.g., a mobile phone, cloud server, or other computing device).

FIG. 31 shows an example image 3105 captured by an eye-tracking subsystem, such as eye-tracking subsystem 3100. In this example, image 3105 may include both the user's pupil 3108 and a glint 3110 near the same. In some examples, pupil 3108 and/or glint 3110 may be identified using an artificial-intelligence-based algorithm, such as a computer-vision-based algorithm. In one embodiment, image 3105 may represent a single frame in a series of frames that may be analyzed continuously in order to track the eye 3102 of the user. Further, pupil 3108 and/or glint 3110 may be tracked over a period of time to determine a user's gaze.

In one example, eye-tracking subsystem 3100 may be configured to identify and measure the inter-pupillary distance (IPD) of a user. In some embodiments, eye-tracking subsystem 3100 may measure and/or calculate the IPD of the user while the user is wearing the artificial reality system. In these embodiments, eye-tracking subsystem 3100 may detect the positions of a user's eyes and may use this information to calculate the user's IPD.

As noted, the eye-tracking systems or subsystems disclosed herein may track a user's eye position and/or eye movement in a variety of ways. In one example, one or more light sources and/or optical sensors may capture an image of the user's eyes. The eye-tracking subsystem may then use the captured information to determine the user's inter-pupillary distance, interocular distance, and/or a 3D position of each eye (e.g., for distortion adjustment purposes), including a magnitude of torsion and rotation (i.e., roll, pitch, and yaw) and/or gaze directions for each eye. In one example, infrared light may be emitted by the eye-tracking subsystem and reflected from each eye. The reflected light may be received or detected by an optical sensor and analyzed to extract eye rotation data from changes in the infrared light reflected by each eye.

The eye-tracking subsystem may use any of a variety of different methods to track the eyes of a user. For example, a light source (e.g., infrared light-emitting diodes) may emit a dot pattern onto each eye of the user. The eye-tracking subsystem may then detect (e.g., via an optical sensor coupled to the artificial reality system) and analyze a reflection of the dot pattern from each eye of the user to identify a location of each pupil of the user. Accordingly, the eye-tracking subsystem may track up to six degrees of freedom of each eye (i.e., 3D position, roll, pitch, and yaw) and at least a subset of the tracked quantities may be combined from two eyes of a user to estimate a gaze point (i.e., a 3D location or position in a virtual scene where the user is looking) and/or an IPD.

In some cases, the distance between a user's pupil and a display may change as the user's eye moves to look in different directions. The varying distance between a pupil and a display as viewing direction changes may be referred to as “pupil swim” and may contribute to distortion perceived by the user as a result of light focusing in different locations as the distance between the pupil and the display changes. Accordingly, measuring distortion at different eye positions and pupil distances relative to displays and generating distortion corrections for different positions and distances may allow mitigation of distortion caused by pupil swim by tracking the 3D position of a user's eyes and applying a distortion correction corresponding to the 3D position of each of the user's eyes at a given point in time. Thus, knowing the 3D position of each of a user's eyes may allow for the mitigation of distortion caused by changes in the distance between the pupil of the eye and the display by applying a distortion correction for each 3D eye position. Furthermore, as noted above, knowing the position of each of the user's eyes may also enable the eye-tracking subsystem to make automated adjustments for a user's IPD.

In some embodiments, a display subsystem may include a variety of additional subsystems that may work in conjunction with the eye-tracking subsystems described herein. For example, a display subsystem may include a varifocal subsystem, a scene-rendering module, and/or a vergence-processing module. The varifocal subsystem may cause left and right display elements to vary the focal distance of the display device. In one embodiment, the varifocal subsystem may physically change the distance between a display and the optics through which it is viewed by moving the display, the optics, or both. Additionally, moving or translating two lenses relative to each other may also be used to change the focal distance of the display. Thus, the varifocal subsystem may include actuators or motors that move displays and/or optics to change the distance between them. This varifocal subsystem may be separate from or integrated into the display subsystem. The varifocal subsystem may also be integrated into or separate from its actuation subsystem and/or the eye-tracking subsystems described herein.

In one example, the display subsystem may include a vergence-processing module configured to determine a vergence depth of a user's gaze based on a gaze point and/or an estimated intersection of the gaze lines determined by the eye-tracking subsystem. Vergence may refer to the simultaneous movement or rotation of both eyes in opposite directions to maintain single binocular vision, which may be naturally and automatically performed by the human eye. Thus, a location where a user's eyes are verged is where the user is looking and is also typically the location where the user's eyes are focused. For example, the vergence-processing module may triangulate gaze lines to estimate a distance or depth from the user associated with intersection of the gaze lines. The depth associated with intersection of the gaze lines may then be used as an approximation for the accommodation distance, which may identify a distance from the user where the user's eyes are directed. Thus, the vergence distance may allow for the determination of a location where the user's eyes should be focused and a depth from the user's eyes at which the eyes are focused, thereby providing information (such as an object or plane of focus) for rendering adjustments to the virtual scene.

The vergence-processing module may coordinate with the eye-tracking subsystems described herein to make adjustments to the display subsystem to account for a user's vergence depth. When the user is focused on something at a distance, the user's pupils may be slightly farther apart than when the user is focused on something close. The eye-tracking subsystem may obtain information about the user's vergence or focus depth and may adjust the display subsystem to be closer together when the user's eyes focus or verge on something close and to be farther apart when the user's eyes focus or verge on something at a distance.

The eye-tracking information generated by the above-described eye-tracking subsystems may also be used, for example, to modify various aspect of how different computer-generated images are presented. For example, a display subsystem may be configured to modify, based on information generated by an eye-tracking subsystem, at least one aspect of how the computer-generated images are presented. For instance, the computer-generated images may be modified based on the user's eye movement, such that if a user is looking up, the computer-generated images may be moved upward on the screen. Similarly, if the user is looking to the side or down, the computer-generated images may be moved to the side or downward on the screen. If the user's eyes are closed, the computer-generated images may be paused or removed from the display and resumed once the user's eyes are back open.

The above-described eye-tracking subsystems can be incorporated into one or more of the various artificial reality systems described herein in a variety of ways. For example, one or more of the various components of system 3000 and/or eye-tracking subsystem 3100 may be incorporated into augmented-reality system 2500 in FIG. 25 and/or virtual-reality system 2600 in FIG. 26 to enable these systems to perform various eye-tracking tasks (including one or more of the eye-tracking operations described herein).

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

It will be understood that when an element such as a layer or a region is referred to as being formed on, deposited on, or disposed “on” or “over” another element, it may be located directly on at least a portion of the other element, or one or more intervening elements may also be present. In contrast, when an element is referred to as being “directly on” or “directly over” another element, it may be located on at least a portion of the other element, with no intervening elements present.

As used herein, the term “approximately” in reference to a particular numeric value or range of values may, in certain embodiments, mean and include the stated value as well as all values within 10% of the stated value. Thus, by way of example, reference to the numeric value “50” as “approximately 50” may, in certain embodiments, include values equal to 50±5, i.e., values within the range 45 to 55.

As used herein, the term “substantially” in reference to a given parameter, property, or condition may mean and include to a degree that one of ordinary skill in the art would understand that the given parameter, property, or condition is met with a small degree of variance, such as within acceptable manufacturing tolerances. By way of example, depending on the particular parameter, property, or condition that is substantially met, the parameter, property, or condition may be at least approximately 90% met, at least approximately 95% met, or even at least approximately 99% met.

While various features, elements or steps of particular embodiments may be disclosed using the transitional phrase “comprising,” it is to be understood that alternative embodiments, including those that may be described using the transitional phrases “consisting of” or “consisting essentially of,” are implied. Thus, for example, implied alternative embodiments to a lens that comprises or includes polycarbonate include embodiments where a lens consists essentially of polycarbonate and embodiments where a lens consists of polycarbonate.

What is claimed is:

1. A polarizing illuminator comprising:
a light source;
a collimator for collimating a light beam emitted by the light source;
a parallel plate having a first surface and a second surface disposed at an acute angle with respect to the light beam, the first surface including a transmissive portion and a reflective portion, and the second surface including a reflective polarizer configured to reflect one polarization of the light beam, transmit an orthogonal polarization of the light beam, and split the light beam into first and second orthogonally polarized sub-beams; and
a retarding wave plate disposed between the reflective portion of the first surface and the reflective polarizer, wherein the retarding wave plate is configured to rotate at least one of the first sub-beam and the second sub-beam to a matched polarization, and the first and second sub-beams having the matched polarization propagate parallel to each other.

2. The polarizing illuminator of claim 1, wherein the light source is configured to emit an unpolarized light beam.

3. The polarizing illuminator of claim 1, wherein the light source comprises a linear array of light emitting diodes.

4. The polarizing illuminator of claim 1, further comprising a second collimator configured to focus the first and second sub-beams to a common location.

5. The polarizing illuminator of claim 1, wherein the reflective portion of the first surface comprises a dielectric thin film stack or a reflective metal.

6. The polarizing illuminator of claim 1, wherein a spacing between the transmission portion of the first surface and the reflective portion of the first surface is less than approximately 0.1 mm.

7. The polarizing illuminator of claim 1, wherein the reflective polarizer comprises a structure selected from the group consisting of a dielectric thin film stack, a wire grid polarizer, and a stack of birefringent films.

8. The polarizing illuminator of claim 1, wherein the retarding waveplate comprises a quarter-wave retarder disposed over the first surface.

9. The polarizing illuminator of claim 1, wherein the retarding waveplate comprises a quarter-wave retarder disposed over the second surface.

10. An image projector coupled to a spatial light modulator (SLM) for forming image light when illuminated by the polarizing illuminator of claim 1.

11. A method comprising:
collimating unpolarized light emitted by a light source to obtain a collimated beam;
using a tilted plate supporting spaced apart full and polarization-selective reflectors to split the collimated beam into first and second orthogonally polarized sub-beams;
using a retarding waveplate to rotate a polarization of at least one of the first sub-beam and the second sub-beam to a matched polarization, wherein the first and second sub-beams propagate parallel to one another; and
focusing the first and second sub-beams.

12. The method of claim 11, further comprising:
collimating unpolarized light of a laterally extending array of light sources including the light source;
using the tilted plate to split the collimated beam emitted by each light source into first and second orthogonally polarized sub-beams; and
rotating a polarization of at least one of the first sub-beam and the second sub-beam to the matched polarization.

13. A display lighting system, comprising:
an ultraviolet (UV) light source;
a color-conversion layer that converts UV light from the UV light source to visible light;
a reflective filter disposed between the UV light source and the color-conversion layer, wherein the reflective filter reflects the visible light and permits passage of the UV light; and
a reflective polarizer that permits passage of the visible light that is in a particular polarization state and reflects other light.

14. The display lighting system of claim 13, wherein the color conversion layer comprises an array of quantum dots.

15. The display lighting system of claim 13, wherein the reflective polarizer comprises a nano-wire grid.

16. The display lighting system of claim 13, further comprising a UV pass filter between the light source and the reflective filter.

17. The display lighting system of claim 13, further comprising an additional reflective filter between the color-conversion layer and the reflective polarizer.

18. The display lighting system of claim 13, further comprising a UV filter between the color conversion layer and the reflective polarizer.

19. The display lighting system of claim 13, further comprising an additional reflective filter between the color-conversion layer and the UV filter.

20. The display lighting system of claim 13, wherein the system is configured to output visible light.
